(19) United States
(12) Patent Application Publication
(10) Pub. No.: US 2026/0130089 A1
(43) Pub. Date: May 7, 2026

(54) DISPLAY PANEL AND ELECTRONIC APPARATUS INCLUDING THE SAME

(71) Applicant: Samsung Display Co., Ltd., Yongin-si (KR)

(72) Inventors: Hyuk Kim, Yongin-si (KR); Seungsoo Baek, Yongin-si (KR); Boyong Chung, Yongin-si (KR); Jonghee Kim, Yongin-si (KR)

(73) Assignee: Samsung Display Co., Ltd., Yongin-si (KR)

(21) Appl. No.: 19/280,490

(22) Filed: Jul. 25, 2025

(30) Foreign Application Priority Data
Nov. 1, 2024 (KR) 10-2024-0153717

(51) Int. Cl. H10K 59/80; H10K 59/122; H10K 59/123

(52) U.S. Cl. CPC H10K 59/80515; H10K 59/122; H10K 59/123

(57) ABSTRACT

A display panel includes a pixel circuit set including a first pixel circuit, a second pixel circuit, and a third pixel circuit, a first pixel electrode overlapping the first pixel circuit in a plan view, a second pixel electrode overlapping the second pixel circuit in a plan view, a third pixel electrode overlapping the third pixel circuit in a plan view, and a connection electrode arranged below the first pixel electrode, the second pixel electrode, and the third pixel electrode. In a plan view, an end of the connection electrode overlaps the first pixel electrode, and another end of the connection electrode overlaps the second pixel electrode.

### CROSS-REFERENCE TO RELATED APPLICATION(S)

This application claims priority to and the benefits of Korean Patent Application No. 10-2024-0153717 under 35 U.S.C. § 119, filed on Nov. 1, 2024, in the Korean Intellectual Property Office (KIPO), the entire contents of which are incorporated herein by reference.

### BACKGROUND

### 1. Technical Field

Embodiments relate to a display panel and an electronic apparatus including the same.

### 2. Description of the Related Art

A display panel may include multiple pixels. Each pixel may include subpixels that emit light of different colors. Each of the subpixels may include a light-emitting element including an emission layer, and a pixel circuit configured to control the luminance of the light-emitting element. The pixel circuit may include thin-film transistors, capacitors, and lines.

Recently, display panels have become thinner and lighter and thus may be applied to various electronic apparatuses. Because the display panels as described above are widely used, various forms of display panels and electronic apparatuses including the same have been designed.

### SUMMARY

Defects in some of pixel circuits may cause bright spots or dark spots to appear on a display panel. In this regard, embodiments include a display panel that displays high-quality images by using a repair process of connecting, to a normal pixel circuit, light-emitting diodes connected to a defective pixel circuit, and an electronic apparatus including the display panel. However, the scope of the disclosure is not limited thereto.

Additional aspects will be set forth in part in the description that follows and, in part, will be apparent from the description, or may be learned by practice of the embodiments of the disclosure.

According to an embodiment, a display panel may include a pixel circuit set including a first pixel circuit, a second pixel circuit, and a third pixel circuit, a first pixel electrode overlapping the first pixel circuit in a plan view, a second pixel electrode overlapping the second pixel circuit in a plan view, a third pixel electrode overlapping the third pixel circuit in a plan view, and a connection electrode arranged below the first pixel electrode, the second pixel electrode, and the third pixel electrode. In a plan view, an end of the connection electrode may overlap the first pixel electrode, and another end of the connection electrode may overlap the second pixel electrode.

In an embodiment, the display panel may further include a bank layer arranged over the first pixel electrode, the second pixel electrode, and the third pixel electrode, the bank layer including a first opening overlapping the first pixel electrode, a second opening overlapping the second pixel electrode, and a third opening overlapping the third pixel electrode in a plan view.

In an embodiment, the first opening may be larger than the second opening and the third opening in a plan view, and the second opening may be smaller than the third opening in a plan view.

In an embodiment, the second pixel electrode may include a first portion and a second portion, the first portion overlapping the second opening in a plan view, and the second portion being spaced apart from the first portion with a gap between the first portion and the second portion, and in a plan view, the gap may extend along a portion of an edge of the second opening.

In an embodiment, the second portion may include a contact portion electrically connected to the second pixel circuit, and the connection electrode may connect the first pixel electrode and the second portion to each other.

In an embodiment, the second pixel electrode and the third pixel electrode may be adjacent to each other in a first direction, and the second pixel electrode may include a protrusion protruding in a second direction intersecting the first direction.

In an embodiment, the second portion may include the protrusion.

In an embodiment, each of the first pixel circuit, the second pixel circuit, and the third pixel circuit may include a first transistor including a gate, a first terminal, and a second terminal, the gate being connected to a first node, the first terminal being connected to a driving voltage line, and the second terminal being connected to a second node, a second transistor connected between the first node and one of a first data line, a second data line, and a third data line, a third transistor connected between an initialization-sensing line and the second node, and a capacitor connected between the first node and the second node.

In an embodiment, the second transistor of the first pixel circuit may be connected to the first data line, the second node of the first pixel circuit may be connected to the first pixel electrode, the second transistor of the second pixel circuit may be connected to the second data line, the second node of the second pixel circuit may be connected to the second pixel electrode, the third transistor of the third pixel circuit may be connected to the third data line, and the second node of the third pixel circuit may be connected to the third pixel electrode.

In an embodiment, the second transistor of the second pixel circuit may be connected to the first data line, and the second node of the second pixel circuit may be connected to the first pixel electrode.

According to an embodiment, a display panel may include a pixel circuit set including a first pixel circuit, a second pixel circuit, and a third pixel circuit, a first pixel electrode overlapping the first pixel circuit in a plan view, a second pixel electrode overlapping the second pixel circuit in a plan view, a third pixel electrode overlapping the third pixel circuit in a plan view, and a connection electrode that connects the first pixel electrode and the second pixel electrode to each other. The second pixel electrode may include a first portion and a second portion, the second portion being spaced apart from the first portion with a gap between the first portion and the second portion and connected to the connection electrode.

In an embodiment, the display panel may further include a bank layer arranged over the first pixel electrode, the second pixel electrode, and the third pixel electrode, the bank layer including a first opening overlapping the first pixel electrode, a second opening overlapping the second pixel electrode, and a third opening overlapping the third pixel electrode in a plan view.

In an embodiment, the first opening may be larger than the second opening and the third opening in a plan view, and the second opening may be smaller than the third opening in a plan view.

In an embodiment, in a plan view, the gap may extend along a portion of an edge of the second opening.

In an embodiment, the second portion may include a contact portion electrically connected to the second pixel circuit, and the connection electrode may connect the first pixel electrode and the second portion to each other.

In an embodiment, the second pixel electrode and the third pixel electrode may be adjacent to each other in a first direction, and the second pixel electrode may include a protrusion protruding in a second direction intersecting the first direction.

In an embodiment, the first portion may include the protrusion.

In an embodiment, the second portion may include the protrusion.

According to an embodiment, an electronic apparatus may include a display panel, and a processor that drives the display panel. The display panel may include a pixel circuit set including a first pixel circuit, a second pixel circuit, and a third pixel circuit, a first pixel electrode overlapping the first pixel circuit in a plan view, a second pixel electrode overlapping the second pixel circuit in a plan view, a third pixel electrode overlapping the third pixel circuit in a plan view, and a connection electrode arranged below the first pixel electrode, the second pixel electrode, and the third pixel electrode. In a plan view, an end of the connection electrode overlaps the first pixel electrode, and another end of the connection electrode overlaps the second pixel electrode.

According to an embodiment, an electronic apparatus may include a display panel, and a processor that drives the display panel. The display panel may include a pixel circuit set including a first pixel circuit, a second pixel circuit, and a third pixel circuit, a first pixel electrode overlapping the first pixel circuit in a plan view, a second pixel electrode overlapping the second pixel circuit in a plan view, a third pixel electrode overlapping the third pixel circuit in a plan view, and a connection electrode that connects the first pixel electrode and the second pixel electrode to each other. The second pixel electrode may include a first portion and a second portion, the second portion being spaced apart from the first portion with a gap between the first portion and the second portion and connected to the connection electrode.

Other aspects, features, and advantages than those described above will become apparent from the following drawings, claims, and detailed description.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of an electronic apparatus according to an embodiment;

FIG. 2 is a schematic cross-sectional view of each subpixel of a display panel, according to an embodiment;

FIG. 3 is a schematic diagram of each optical portion of a color conversion-transmitting layer of FIG. 2;

FIG. 4 is a schematic diagram of an equivalent circuit of a normal pixel according to an embodiment;

FIG. 5 is a schematic diagram of an equivalent circuit of a repaired pixel according to an embodiment;

FIG. 6 is a schematic plan view of an area of a display panel according to an embodiment;

FIG. 7 is a schematic cross-sectional view of the display panel of FIG. 6 taken along line I-I′ of FIG. 6;

FIG. 8A is a schematic plan view of an area of a display panel according to an embodiment;

FIG. 8B is a plan view illustrating a second pixel electrode shown in FIG. 8A;

FIG. 9 is a schematic cross-sectional view of the display pane of FIG. 8AI taken along line II-II′ of FIG. 8A;

FIG. 10 is a schematic plan view of an area of a display panel according to an embodiment;

FIG. 11 is a schematic cross-sectional view of the display panel of FIG. 10 taken along line III-III′ of FIG. 10;

FIG. 12A is a schematic plan view of an area of a display panel according to an embodiment;

FIG. 12B is a plan view illustrating a second pixel electrode shown in FIG. 12A;

FIG. 13 is a schematic plan view of an area of a display panel according to an embodiment; and

FIG. 14 is a schematic block diagram of an electronic apparatus according to an embodiment.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

As various modifications may be applied and numerous embodiments may be implemented, particular embodiments will be illustrated in the drawings and described in detail in the written description. Effects and features, and methods for achieving them will be clarified with reference to embodiments described below in detail with reference to the drawings. However, the embodiments may have different forms and should not be construed as being limited to the descriptions set forth herein.

Hereinafter, the embodiments will now be described in detail with reference to the accompanying drawings. When described with reference to the drawings, identical or corresponding elements will be given the same reference numerals, and redundant description of these elements will be omitted.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

As used herein, the singular forms include the plural forms unless the context clearly indicates otherwise.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

In the specification, the x-axis, the y-axis, and the z-axis are not limited to directions according to three axes of the rectangular coordinate system and may be interpreted in a broader sense. For example, the x-axis, the y-axis, and the z-axis may be orthogonal to each other, but may refer to different directions that are not orthogonal to each other.

In the specification, the term “plane” refers to when a target portion is viewed from above (e.g., when viewed in a direction perpendicular to the upper surface of a substrate), and the term “cross-sectional” refers to when a vertically cut cross-section of the target portion is viewed from the side.

In the specification, when a first element overlaps a second element, it may mean that the first element is arranged over or below the second element and at least partially overlaps the second element in a plan view.

In the specification, the term “ON” used in association with the state of an element may refer to an activated state of the element, and “OFF” may refer to a deactivated state of the element. The term “ON” used in association with a signal received by an element may refer to a signal that activates the element, and “OFF” may refer to a signal that deactivates the element. The element may be activated by a high-level voltage or a low-level voltage. For example, a P-channel transistor (P-type transistor) is activated by a low level voltage, and an N-channel transistor (N-type transistor) is activated by a high level voltage. Accordingly, it should be understood that “ON” voltages for the P-type transistor and the N-type transistor are opposite (low vs. high) voltage levels.

In the specification, when a certain embodiment may be implemented differently, a specific process order may also be performed differently from the described order. As an example, two processes that are successively described may be performed substantially simultaneously or performed in an order opposite to the order described.

Sizes of elements in the drawings may be exaggerated for convenience of description. For example, because sizes and thicknesses of elements in the drawings are arbitrarily illustrated for convenience of explanation, the following embodiments are not limited thereto.

The term “about” may include variations of, for example, +20%, +10%, or +5%, from the specified numerical value unless otherwise expressly stated. In some contexts, the term may account for rounding, inherent measurement limitations, or standard tolerances recognized in the relevant technical field. When applied to dimensions, concentrations, or other quantifiable parameters, “about” may include minor deviations that would be understood by a person of ordinary skill in the art as insubstantial in the given context. The scope of “about” should be interpreted in view of standard experimental or clinical tolerances applicable to the field of use. A person skilled in the art would recognize that “about” allows for practical deviations that do not materially alter the intended properties of the invention. Similarly, for mechanical dimensions, “about” may include deviations that are within industry-accepted tolerances and do not materially impact the performance of the disclosure.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

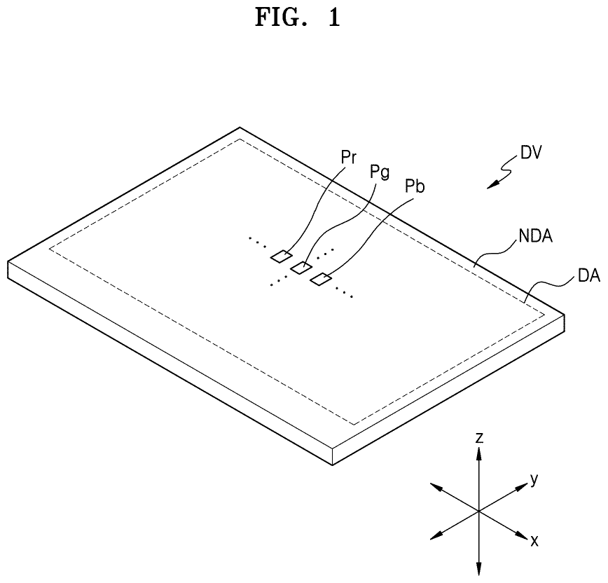

FIG. 1 is a schematic perspective view of an electronic apparatus DV according to an embodiment.

Referring to FIG. 1, the electronic apparatus DV may include a display area DA and a non-display area NDA outside the display area DA.

The electronic apparatus DV may provide an image through an array of multiple pixels that are two-dimensionally arranged on a plane in the display area DA. Each of the pixels may include a first subpixel Pg, a second subpixel Pb, and a third subpixel Pr. The first subpixel Pg, the second subpixel Pb, and the third subpixel Pr may be areas that may emit red, green, and blue light, respectively. The electronic apparatus DV may provide an image by using light emitted from the subpixels.

The non-display area NDA may be an area in which subpixels are not arranged, and where no image is provided. The non-display area NDA may surround at least a portion of the display area DA in a plan view. A driver or a power line configured to provide an electrical signal or power to subpixel circuits (hereinafter, also referred to as pixel circuits) may be arranged in the non-display area NDA. The non-display area NDA may include pads that electrically connect a display panel, a printed circuit board, and electronic elements to each other.

The display area DA may have a polygonal shape in a plan view. For example, as shown in FIG. 1, the display area DA may have a rectangular shape of which length in a first direction (e.g., an x-direction) is greater than the length in a second direction (e.g., a y-direction). For example, the display area DA may have a rectangular shape of which length in the first direction (e.g., the x-direction) is smaller than the length in the second direction (e.g., the y-direction), or may have a square shape. In another embodiment, the display area DA may have various shapes, such as an elliptical shape or a circular shape.

The electronic apparatus DV according to embodiments may be a display apparatus that displays a moving picture or a still image, and may be various electronic apparatuses including not only portable electronic apparatuses, such as a mobile phone, a smartphone, a tablet personal computer (PC), a mobile communication terminal, an electronic notebook, an electronic book, a portable multimedia player (PMP), a navigation device, or an ultra-mobile PC (UMPC), but also a television, a laptop computer, a monitor, a billboard, and an Internet-of-things (IoT) device. The electronic apparatus DV according to an embodiment may be a wearable device, such as a smart watch, a watch phone, a glasses-type display, or a head mounted display (HMD). The electronic apparatus DV according to an embodiment may be a center information display (CID) located on an instrument panel, a center fascia, or a dashboard of a vehicle, a room mirror display replacing a side-view mirror of a vehicle, or a user interface apparatus located on the back of a front seat for entertainment for a back seat of a vehicle.

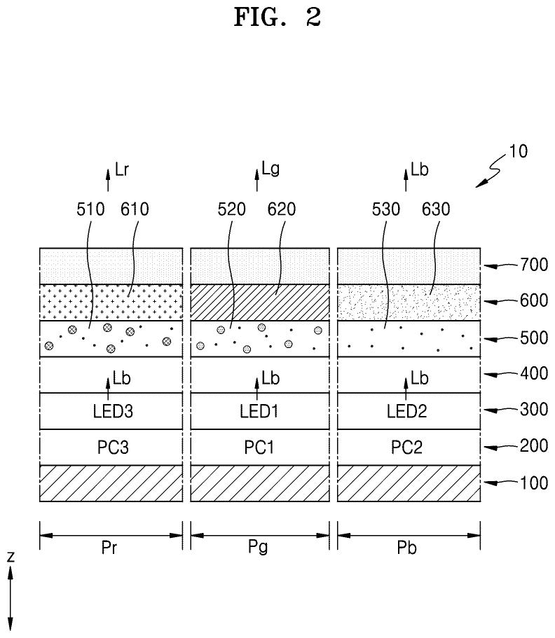

FIG. 2 is a schematic cross-sectional view of each subpixel of a display panel 10, according to an embodiment.

Referring to FIG. 2, the display panel 10 may include a substrate 100, a circuit layer 200, a light-emitting diode layer 300, an encapsulation layer 400, a color conversion-transmitting layer 500, a color filter layer 600, and a transmissive substrate layer 700.

The substrate 100 may include glass, a metal, or a polymer resin. In case that the substrate 100 is flexible or bendable, the substrate 100 may include a polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. Various modifications may be made. For example, the substrate 100 may have a multilayer structure including two layers including a polymer resin and a barrier layer that includes an inorganic material (e.g., silicon oxide, silicon nitride, or silicon oxynitride) and is positioned between the two layers.

The circuit layer 200 and the light-emitting diode layer 300 may be arranged over the substrate 100. The circuit layer 200 may include first, second, and third pixel circuits PC1, PC2, and PC3, and the first to third pixel circuits PC1, PC2, and PC3 may be electrically connected to first, second, and third light-emitting diodes LED1, LED2, and LED3 of the light-emitting diode layer 300, respectively.

The first to third light-emitting diodes LED1, LED2, and LED3 may each include an organic light-emitting diode including an organic material. In another embodiment, the first to third light-emitting diodes LED1, LED2, and LED3 may each include an inorganic light-emitting diode including an inorganic material. The inorganic light-emitting diode may include a PN junction diode including inorganic a semiconductor-based material. The inorganic light-emitting diode may have a width of several to hundreds of micrometers or several to several hundreds of nanometers. In some embodiments, an emission layer of each of the first to third light-emitting diodes LED1, LED2, and LED3 may include an organic material, an inorganic material, quantum dots, an organic material and quantum dots, or an inorganic material and quantum dots.

The first to third light-emitting diodes LED1, LED2, and LED3 may emit light of a same color. For example, the first to third light-emitting diodes LED1, LED2, and LED3 may emit light (e.g., blue light Lb) having a wavelength in a first wavelength band. The first wavelength band may be, for example, in a range of about 450 nm to about 495 nm. Light (e.g., the blue light Lb) emitted from the first to third light-emitting diodes LED1, LED2, and LED3 may pass through the color conversion-transmitting layer 500 after passing through the encapsulation layer 400 on the light-emitting diode layer 300.

The color conversion-transmitting layer 500 may include optical portions that convert the color of light (e.g., the blue light Lb) emitted from the light-emitting diode layer 300 or transmit the light without converting the color of the light. For example, the color conversion-transmitting layer 500 may include color conversion portions that convert the light (e.g., the blue light Lb) emitted from the light-emitting diode layer 300 to light of another color, and a transmission portion that transmits the light (e.g., the blue light Lb) emitted from the light-emitting diode layer 300 without converting the color of the light. The color conversion-transmitting layer 500 may include a second color conversion portion 520 corresponding to the first subpixel Pg, a transmission portion 530 corresponding to the second subpixel Pb, and a first color conversion portion 510 corresponding to the third subpixel Pr. The first color conversion portion 510 may convert light (e.g., the blue light Lb) having a wavelength in the first wavelength band into light (e.g., red light Lr) having a wavelength in a second wavelength band. The second wavelength band may be, for example, in a range of about 630 nm to about 780 nm. The second color conversion portion 520 may convert light (e.g., the blue light Lb) having a wavelength in the first wavelength band into light (e.g., green light Lg) having a wavelength in a third wavelength band. The third wavelength band may be, for example, in a range of about 495 nm to about 570 nm. The transmission portion 530 may transmit light (e.g., the blue light Lb) having a wavelength in the first wavelength band without converting the color of the light. However, the disclosure is not limited thereto. A wavelength band of the light emitted from the light-emitting diode layer 300 (e.g., blue light Lb) and a wavelength band of light after conversion may be modified differently.

The color filter layer 600 may be arranged on the color conversion-transmitting layer 500. The color filter layer 600 may include first, second, and third color filters 610, 620, and 630 of different colors. For example, the first color filter 610 may include a red color filter that only passes light having a wavelength in a range of about 630 nm to about 780 nm. The second color filter 620 may include a green color filter that only passes light having a wavelength in a range of about 495 nm to about 570 nm. The third color filter 630 may include a blue color filter that only passes light having a wavelength in a range of about 455 nm to about 495 nm.

In an embodiment, although not shown in the Drawings, a black matrix may be formed between the first to third color filters 610, 620, and 630. In another embodiment, the first color filter 610 may have openings corresponding to the first subpixel Pg and the second subpixel Pb, the second color filter 620 may have openings corresponding to the third subpixel Pr and the second subpixel Pb, and the third color filter 630 may have openings corresponding to the third subpixel Pr and the first subpixel Pg. A portion, in which the first to third color filters 610, 620, and 630 overlap in a plan view, of an area other than the openings corresponding to the first subpixel Pg, the second subpixel Pb, and the third subpixel Pr may function as a black matrix.

As light color-converted by and light transmitted by the color conversion-transmitting layer 500 pass through the first to third color filters 610, 620, and 630, color purity may be improved. Also, the color filter layer 600 may prevent or significantly reduce external light (e.g., light incident from the outside of the display panel 10 toward the display panel 10) from being reflected and seen by a user.

In an embodiment, the transmissive substrate layer 700 may be included on the color filter layer 600. The transmissive substrate layer 700 may include glass or a transmissive organic material. For example, the transmissive substrate layer 700 may include a transmissive organic material, such as acrylic resin.

In an embodiment, the transmissive substrate layer 700 may be a type of substrate. After the color filter layer 600 and the color conversion-transmitting layer 500 are formed on a surface of the transmissive substrate layer 700, the transmissive substrate layer 700 may be bonded to the substrate 100 so that the color conversion-transmitting layer 500 faces the encapsulation layer 400.

In another embodiment, after the color conversion-transmitting layer 500 and the color filter layer 600 are sequentially formed over the encapsulation layer 400, the transmissive substrate layer 700 may be formed by being directly applied and cured on the color filter layer 600. In an embodiment, although not shown in the Drawings, another optical film, for example, an anti-reflection (AR) film, may be arranged over the transmissive substrate layer 700.

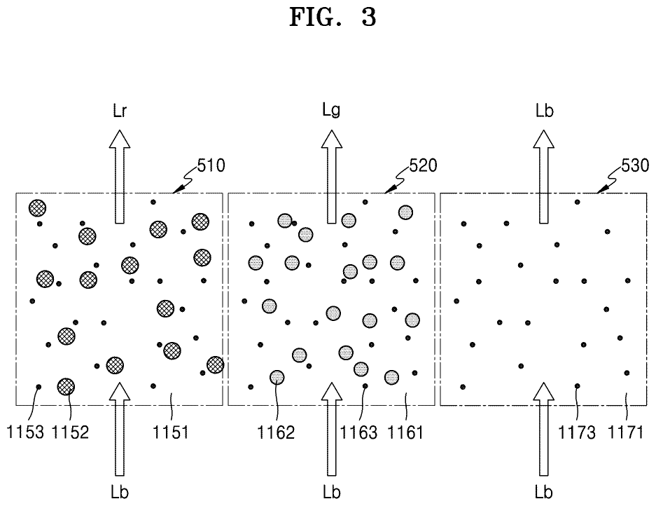

FIG. 3 is a schematic diagram of each optical portion of the color conversion-transmitting layer of FIG. 2.

The first color conversion portion 510 may covert incident blue light Lb into red light Lr. As shown in FIG. 3, the first color conversion portion 510 may include a first photosensitive polymer 1151, and first quantum dots 1152 and first scattering particles 1153 dispersed in the first photosensitive polymer 1151.

The first quantum dots 1152 may be excited by the blue light Lb to isotopically emit the red light Lr having a wavelength greater than the wavelength of the blue light Lb. The first photosensitive polymer 1151 may include an organic material having light transmission properties.

Quantum dots may be crystals of a semiconductor compound and may include a material that may emit light in an emission wavelength band depending on the size of crystals. The diameter of each quantum dot may be, for example, in a range of about 1 nm to about 10 nm.

The quantum dots may be synthesized via a wet chemical process, a metal organic chemical vapor deposition (MOCVD) process, a molecular beam epitaxy (MBE) process, or a similar process. The wet chemical process may be a method of growing quantum dot particle crystals after an organic solvent is mixed with a precursor material. In a wet chemical process, when crystals grow, the organic solvent may naturally function as a dispersant coordinated to the surface of quantum dot crystals and regulate the growth of the crystals, and thus, the wet chemical process may be more readily performed than vapor deposition methods, such as MOCVD or MBE. The wet chemical process may be a low-cost process and may control the growth of quantum dot particles.

The quantum dot may include a group III-VI semiconductor compound, a group II-VI semiconductor compound, a group III-V semiconductor compound, a group I-III-VI semiconductor compound, a group IV-VI semiconductor compound, a group IV element, a group IV compound, or a combination thereof.

Examples of a group III-VI semiconductor compound may include a binary compound, such as GaS, GaSe, Ga2Se3, GaTe, InS, InSe, In2Se3, or InTe, a ternary compound, such as InGaS3 or InGaSe3, or a combination thereof.

Examples of a group II-VI semiconductor compound may include a binary compound, such as CdS, CdSe, CdTe, ZnS, ZnSe, ZnTe, ZnO, HgS, HgSe, HgTe, MgSe, or MgS, a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, or MgZnS, a quaternary compound, such as CdZnSeS, CdZnSeTe, CdZnSTe, CdHgSeS, CdHgSeTe, CdHgSTe, HgZnSeS, HgZnSeTe, or HgZnST, or a combination thereof.

Examples of a group III-V semiconductor compound may include a binary compound, such as GaN, GaP, GaAs, GaSb, AlN, AlP, AlAs, AlSb, InN, InP, InAs, or InSb, a ternary compound, such as GaNP, GaNAs, GaNSb, GaPAs, GaPSb, AlNP, AlNAs, AlNSb, AlPAs, AlPSb, InGaP, InNP, InAIP, InNAs, InNSb, InPAs, or InPSb, a quaternary compound, such as GaAlNAs, GaAlNP, GaAlNSb, GaAlPAs, GaAlPSb, GaInNP, GaInNAs, GaInNSb, GaInPAs, GaInPSb, InAlNP, InAlNAs, InAlNSb, InAlPAs, or InAlPSb, or a combination thereof. In an embodiment, a group III-V semiconductor compound may further include a group II element. Examples of the group III-V semiconductor compound further including a group II element may include InZnP, InGaZnP, or InAlZnP.

Examples of a group I-III-VI semiconductor compound may include a ternary compound, such as AgInS, AgInS₂, CuInS, CuInS₂, CuGaO₂, AgGaO₂, or AgAlO₂, or a combination thereof.

Examples of a group IV-VI semiconductor compound may include a binary compound, such as SnS, SnSe, SnTe, PbS, PbSe, or PbTe, a ternary compound, such as SnSeS, SnSeTe, SnSTe, PbSeS, PbSeTe, PbSTe, SnPbS, SnPbSe, or SnPbTe, a quaternary compound, such as SnPbSSe, SnPbSeTe, or SnPbSTe, or a combination thereof.

A group IV element or a group IV compound may include an element, such as silicon (Si) or germanium (Ge), a binary compound, such as SiC or SiGe, or a combination thereof.

Each element included in a multi-element compound, such as a binary compound, a ternary compound, or a quaternary compound, may be present in particles at a uniform concentration or a non-uniform concentration.

The quantum dot may have a single structure or a core-shell structure in which the concentration of each element included in the quantum dot is uniform. For example, a material included in a core and a material included in a shell may be different. The shell of the quantum dot may function as a protective layer to maintain semiconductor characteristics by preventing chemical denaturation of the core and/or as a charging layer to impart electrophoretic characteristics to the quantum dot. The shell may include a single layer or a multilayer. An interface between the core and the shell may have a concentration gradient in which the concentration of an element present in the shell decreases toward the core.

Examples of the shell of the quantum dot may include a metal oxide, a non-metal oxide, a semiconductor compound, or a combination thereof. Examples of a metal oxide or a non-metal oxide may include a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, a ternary compound, such as MgAl₂O₄, CoFe₂O₄, NiFe₂O₄, or CoMn₂O₄, or a combination thereof. Examples of a semiconductor compound may include a group III-VI semiconductor compound, a group II-VI semiconductor compound, a group III-V semiconductor compound, a group I-III-VI semiconductor compound, a group IV-VI semiconductor compound, or a combination thereof, as described above. For example, a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or a combination thereof.

A quantum dot may have a full width of half maximum (FWHM) of an emission wavelength spectrum less than or equal to about 45 nm. For example, a quantum dot may have a full width of half maximum (FWHM) of an emission wavelength spectrum less than or equal to about 40 nm. For example, a quantum dot may have a full width of half maximum (FWHM) of an emission wavelength spectrum less than or equal to about 30 nm. In this range, color purity or color reproducibility may be improved. Also, because light emitted through the quantum dots is emitted in all directions, the optical viewing angle may be improved.

The shape of the quantum dot may be spherical, pyramidal, multi-armed, or cubic and may be in the form of a nanoparticle, a nanotube, a nanowire, a nanofiber, or a nanoplate-shaped particle.

Because an energy band gap may be adjusted by adjusting the size of the quantum dot, light in various wavelength bands may be obtained from a quantum dot emission layer. Accordingly, by using quantum dots of different sizes, a light-emitting element that emits light having various wavelengths may be implemented. For example, the size of the quantum dot may be selected such that red, green, and/or blue light is emitted. For example, the size of the quantum dot may be configured such that light of various colors are combined to emit white light.

The first scattering particles 1153 may scatter the blue light Lb that is not absorbed by the first quantum dots 1152 to cause more first quantum dots 1152 to be excited such that color conversion efficiency may be increased. The first scattering particles 1153 may be, for example, metal oxide particles or organic particles. For example, the first scattering particles 1153 may include a metal oxide such as titanium oxide (TiO₂), zirconium oxide (ZrO₂), aluminum oxide (Al₂O₃), indium oxide (In₂O₃), zinc oxide (ZnOₓ), or tin oxide (SnO₂), or an organic material such as an acrylic resin or a urethane resin. The scattering particles may scatter light in various directions regardless of an angle of incidence without substantially converting a wavelength of incident light. Accordingly, the scattering particles may improve the side visibility of a display apparatus.

The second color conversion portion 520 may convert the incident blue light Lb into green light Lg. As shown in FIG. 3, the second color conversion portion 520 may include a second photosensitive polymer 1161, and second quantum dots 1162 and second scattering particles 1163 dispersed in the second photosensitive polymer 1161.

The second quantum dots 1162 may be excited by the blue light Lb to isotopically emit the green light Lg having a wavelength greater than the wavelength of the blue light Lb. The second photosensitive polymer 1161 may include an organic material having light transmission properties.

The second scattering particles 1163 may scatter the blue light Lb that is not absorbed by the second quantum dots 1162 to cause more second quantum dots 1162 to be excited such that the color conversion efficiency may be increased. Because the description of the first quantum dots 1152 and the first scattering particles 1153 may be applied to the second quantum dots 1162 and the second scattering particles 1163, respectively, the description of the second quantum dots 1162 and the second scattering particles 1163 is omitted.

In some embodiments, the first quantum dots 1152 and the second quantum dots 1162 may include a same material, and the size of the first quantum dots 1152 may be greater than the size of the second quantum dots 1162.

The transmission portion 530 may transmit the blue light Lb incident on the transmission portion 530 without converting the color of the blue light Lb. Accordingly, the transmission portion 530 may not have quantum dots. As shown in FIG. 3, the transmission portion 530 may include a third photosensitive polymer 1171 in which third scattering particles 1173 are dispersed. For example, the third photosensitive polymer 1171 may include, for example, an organic material having light transmission properties, such as a silicon resin or an epoxy resin, and the third photosensitive polymer 1171 and the first and second photosensitive polymers 1151 and 1161 may include a same material. The third scattering particles 1173 may scatter and emit the blue light Lb, and the third scattering particles 1173 and the first and second scattering particles 1153 and 1163 may include a same material.

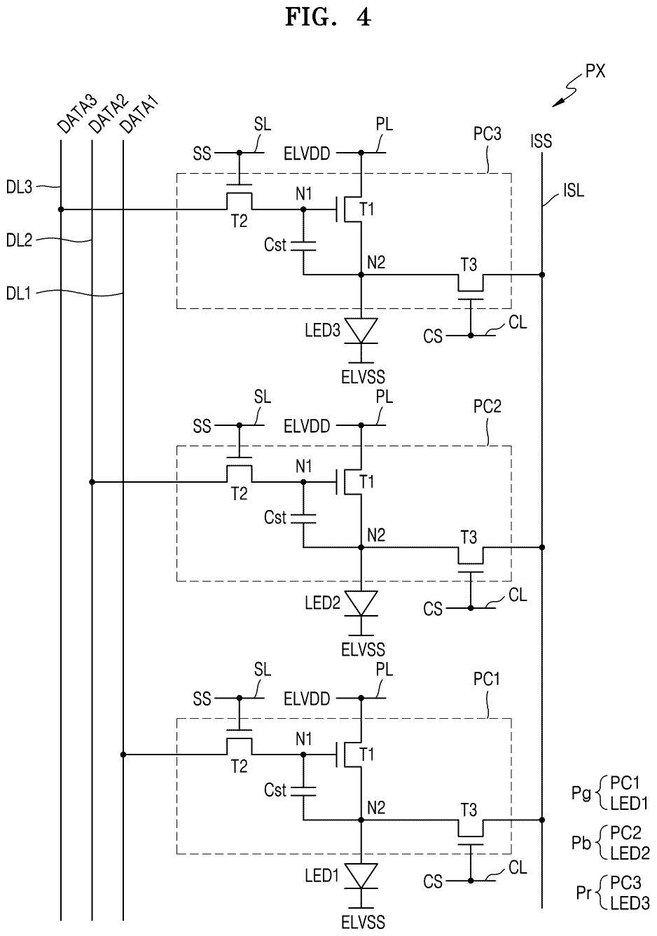

FIG. 4 is a schematic diagram of an equivalent circuit of a normal pixel according to an embodiment.

FIG. 4 is a schematic diagram of a pixel PX included in a display panel, according to an embodiment. The pixel PX may include a first subpixel Pg, a second subpixel Pb, and a third subpixel Pr. The first subpixel Pg may include a first light-emitting diode LED1 that emits light of a first color, and a first pixel circuit PC1 electrically connected to the first light-emitting diode LED1. The second subpixel Pb may include a second light-emitting diode LED2 that emits light of a second color, and a second pixel circuit PC2 electrically connected to the second light-emitting diode LED2. The third subpixel Pr may include a third light-emitting diode LED3 that emits light of a third color, and a third pixel circuit PC3 electrically connected to the third light-emitting diode LED3. A set of the first to third pixel circuits PC1, PC2, and PC3 included in a pixel PX may be referred to as a pixel circuit set.

Referring to FIG. 4, each of the first to third light-emitting diodes LED1, LED2, and LED3 may include an organic light-emitting diode. A pixel electrode (e.g., an anode) of each of the first to third light-emitting diodes LED1, LED2, and LED3 may be electrically connected to a corresponding pixel circuit, and a common electrode (e.g., a cathode) of each of the first to third light-emitting diodes LED1, LED2, and LED3 may be electrically connected to a common voltage line configured to transmit a common power voltage ELVSS.

Each of the first to third pixel circuits PC1, PC2, and PC3 may include a first transistor T1, a second transistor T2, a third transistor T3, and a storage capacitor Cst. Each of the first transistor T1, the second transistor T2, and the third transistor T3 may include an oxide semiconductor thin-film transistor including a semiconductor layer including an oxide semiconductor, or may include a silicon semiconductor thin-film transistor including a semiconductor layer including polysilicon. The first to third pixel circuits PC1, PC2, and PC3 may have a same or similar structures. Hereinafter, the first pixel circuit PC1 is described.

The first transistor T1 may be a driving transistor. A first terminal of the first transistor T1 may be electrically connected to a driving voltage line PL configured to supply a driving power voltage ELVDD, and a second terminal of the first transistor T1 may be electrically connected to a second node N2. A gate electrode of the first transistor T1 may be electrically connected to a first node N1. The first transistor T1 may be configured to control the amount of current flowing from the driving voltage line PL to the first light-emitting diode LED1 in response to a voltage of the first node N1.

The second transistor T2 may be a switching transistor. A first terminal of the second transistor T2 of the first pixel circuit PC1 may be electrically connected to a first data line DL1, and a second terminal of the second transistor T2 may be electrically connected to the first node N1. A gate electrode of the second transistor T2 may be electrically connected to a scan line SL. In case that a scan signal SS is supplied through the scan line SL, the second transistor T2 may be turned on and configured to electrically connect the first data line DL1 to the first node N1 and transmit, to the first node N1, a first data signal DATA1 from the first data line DL1.

The third transistor T3 may be an initialization-sensing transistor. A first terminal of the third transistor T3 may be electrically connected to an initialization sensing-line ISL, and a second terminal of the third transistor T3 may be electrically connected to a second node N2. A gate electrode of the third transistor T3 may be electrically connected to a control line CL. In case that a control signal CS is supplied through the control line CL, the third transistor T3 may be turned on and configured to electrically connect the initialization sensing-line ISL to the second node N2 and transmit, to the second node N2, an initialization-sensing signal ISS from the initialization sensing-line ISL.

In an embodiment, in case that the third transistor T3 is turned on, the third transistor T3 may be configured to initialize a potential of the pixel electrode of the first light-emitting diode LED1 by using, as an initialization voltage, the initialization-sensing signal ISS from the initialization sensing-line ISL. In an embodiment, in case that the third transistor T3 is turned on, the third transistor T3 may be configured to sense characteristic information about the first light-emitting diode LED1. As described above, the third transistor T3 may have both the function of an initialization transistor and the function of a sensing transistor, or may have only one of the functions. In case that the third transistor T3 functions as an initialization transistor, the initialization sensing-line ISL may be regarded as an initialization voltage line, and in case that the third transistor T3 functions as a sensing transistor, the initialization sensing-line ISL may be regarded as a sensing line. An initialization operation and a sensing operation of the third transistor T3 may be performed separately or simultaneously. In other words, the third transistor T3 may be an initialization transistor and/or a sensing transistor. Hereinafter, for convenience of description, an embodiment that the third transistor T3 has both the functions of the initialization transistor and the sensing transistor is described.

The storage capacitor Cst may be connected between the first node N1 and the second node N2. For example, a capacitor electrode of the storage capacitor Cst may be electrically connected to the gate electrode of the first transistor T1, and another capacitor electrode of the storage capacitor Cst may be electrically connected to the pixel electrode of the first light-emitting diode LED1.

The second transistor T2 of each of the first to third pixel circuits PC1, PC2, and PC3 may be electrically connected to a corresponding data line among the first data line DL1, a second data line DL2, and a third data line DL3. For example, a first terminal of the second transistor T2 of the second pixel circuit PC2 may be electrically connected to the second data line DL2 configured to transmit a second data signal DATA2, and a first terminal of the second transistor T2 of the third pixel circuit PC3 may be electrically connected to the third data line DL3 configured to transmit a third data signal DATA3. A second node N2 of each of the first to third pixel circuits PC1, PC2, and PC3 may be electrically connected to a pixel electrode of a corresponding light-emitting diode among the first light-emitting diode LED1, the second light-emitting diode LED2, and the third light-emitting diode LED3.

FIG. 4 illustrates that each of the first to third pixel circuits PC1, PC2, and PC3 includes three transistors (e.g., the first to third transistors T1 to T3) and one storage capacitor Cst, but the disclosure is not limited thereto. The number of transistors or the number of capacitors included in each of the first to third pixel circuits PC1, PC2, and PC3 may vary.

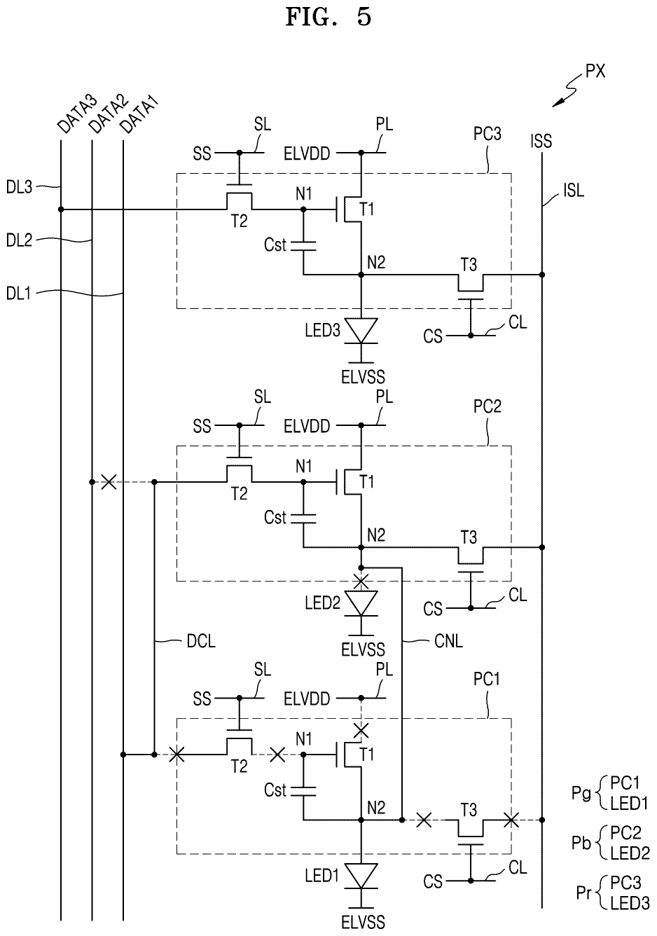

FIG. 5 is a schematic diagram of an equivalent circuit of a repaired pixel according to an embodiment.

FIG. 5 may be similar to FIG. 4, but shows an embodiment that the first pixel circuit PC1 is a defective pixel circuit. The first light-emitting diode LED1 may be electrically connected to a second node N2 of the second pixel circuit PC2 through a connection line CNL.

Referring to FIG. 5, in the first pixel circuit PC1, the first terminal of the first transistor T1 may be electrically disconnected from the driving voltage line PL. The first terminal of the second transistor T2 may be electrically disconnected from the first data line DL1, and the second terminal of the second transistor T2 may be electrically disconnected from the first node N1. The first terminal of the third transistor T3 may be electrically disconnected from the initialization sensing-line ISL, and the second terminal of the third transistor T3 may be electrically disconnected from the second node N2.

In the second pixel circuit PC2, the first terminal of the second transistor T2 may be electrically disconnected from the second data line DL2 and may be electrically connected to the first data line DL1 through a data connection line DCL. The second light-emitting diode LED2 may be electrically disconnected from the second node N2. The second node N2 of the second pixel circuit PC2 may be electrically connected to the first light-emitting diode LED1 through the connection line CNL.

In an embodiment, during a process of manufacturing the display panel 10, the first to third pixel circuits PC1, PC2, and PC3 may be inspected for defects by using an optical method. During an inspection process, in case that a defect is identified in the first pixel circuit PC1, a repair process may be performed for the corresponding pixel PX. On the rear surface of the substrate 100, a laser beam may be irradiated to electrically disconnect each of a portion that connects the driving voltage line PL and the first transistor T1 of the first pixel circuit PC1 to each other, a portion that connects the second transistor T2 and the first data line DL1 to each other, a portion that connects the second transistor T2 and the gate electrode of the first transistor T1 to each other, a portion that connects the third transistor T3 and the control line CL to each other, and a portion that connects the third transistor T3 and the second node N2 to each other. Also, the second light-emitting diode LED2 and the second node N2 of the second pixel circuit PC2 may be electrically disconnected by irradiating a laser beam to a portion that connects the second light-emitting diode LED2 and the second node N2 of the second pixel circuit PC2 to each other. For example, the pixel electrode of the second light-emitting diode LED2 may include a first portion including an emission area, and a second portion that connects the second light-emitting diode LED2 and the second node N2 of the second pixel circuit PC2 to each other, and the first portion and the second portion may be separated from each other and electrically disconnected by a laser beam.

The first data line DL1 and the first terminal of the second transistor T2 of the second pixel circuit PC2 may be electrically connected by irradiating a laser beam to the data connection line DCL. The pixel electrode of the first light-emitting diode LED1 and the second node N2 of the second pixel circuit PC2 may be electrically connected to each other by irradiating a laser beam to the connection line CNL or by forming the connection line CNL. The connection line CNL may include a second portion of the pixel electrode of the second light-emitting diode LED2. Through such a repair process, the first data line DL1 and the first light-emitting diode LED1 may be electrically connected to the second pixel circuit PC2.

In an embodiment, the first light-emitting diode LED1 may include a green light-emitting diode that emits green light, and the second light-emitting diode LED2 may include a blue light-emitting diode that emits blue light. In white light, the proportion of blue light may be approximately 10%, the proportion of red light may be approximately 20%, and the proportion of green light may be approximately 70%. Accordingly, in case that the first light-emitting diode LED1 does not emit light due to a defect in the first pixel circuit PC1, a user may recognize a spot in an image in case that the electronic apparatus DV (see FIG. 1) displays a white image. In contrast, according to an embodiment, in case that the second pixel circuit PC2 is connected to the first light-emitting diode LED1, and the second light-emitting diode LED2 does not emit light while the first light-emitting diode LED1 emits light, image spotting may be reduced or may not be visible. Accordingly, according to embodiments, in case that a defect occurs in the first pixel circuit PC1, by electrically connecting the second pixel circuit PC2 and the first light-emitting diode LED1 to each other, the display panel 10 (see FIG. 2) or the electronic apparatus DV (FIG. 1) may display high-quality images to a user.

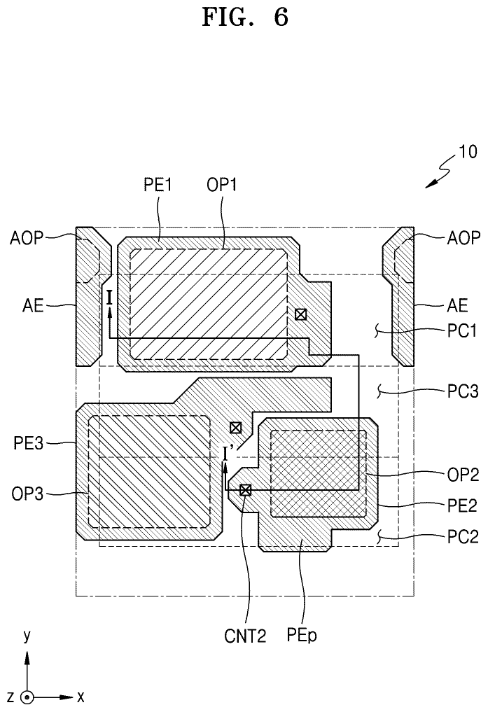

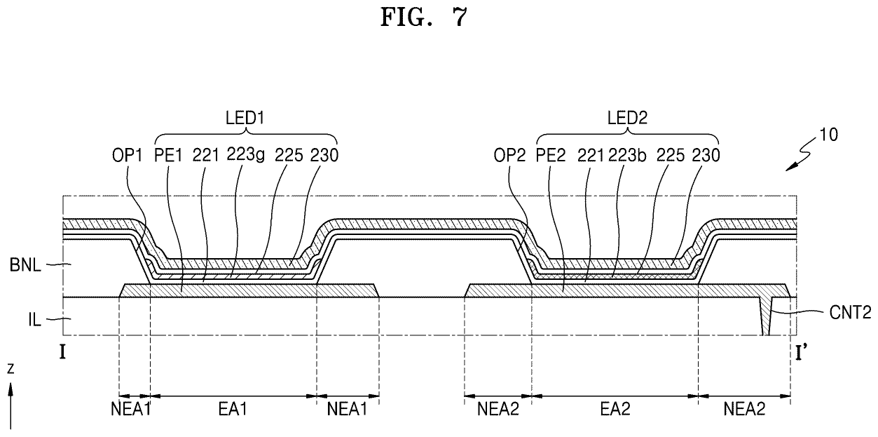

FIG. 6 is a schematic plan view of an area of the display panel 10 according to an embodiment, and FIG. 7 is a schematic cross-sectional view of the display panel 10 taken along line I-I′ of FIG. 6.

FIG. 6 is a schematic diagram of an area of the light-emitting diode layer 300 described above with reference to FIG. 2. For example, a pixel electrode layer including a pixel electrode of each of the first to third light-emitting diodes LED1, LED2, and LED3 is schematically shown. The circuit layer 200 may be arranged below a light-emitting diode layer, and the circuit layer 200 may include first to third pixel circuits PC1, PC2, and PC3. The first to third pixel circuits PC1, PC2, and PC3 indicated by dotted lines in FIG. 6 represent areas where elements, for example, transistors and capacitors, forming each of the first to third pixel circuits PC1, PC2, and PC3 are arranged in a plan view. In an embodiment, the first pixel circuit PC1, the third pixel circuit PC3, and the second pixel circuit PC2 may be sequentially arranged in a second direction (e.g., a y-direction). In other words, the first pixel circuit PC1 and the second pixel circuit PC2 may be arranged in the second direction (e.g., the y-direction), and the third pixel circuit PC3 may be disposed between the first pixel circuit PC1 and the second pixel circuit PC2. The first to third pixel circuits PC1, PC2, and PC3 and the first to third light-emitting diodes LED1, LED2, and LED3 may form one pixel PX as described above with reference to FIG. 4.

Referring to FIGS. 6 and 7 together, the display panel 10 may include an insulating layer IL arranged over the substrate 100. The insulating layer IL may be arranged over the first to third pixel circuits PC1, PC2, and PC3 and may include a planarization layer for providing a flat base surface for the pixel electrode layer. The insulating layer IL may include an organic insulating material. For example, the insulating layer IL may include a photoresist, benzocyclobutene (BCB), polyimide, hexamethyldisiloxane (HMDSO), polymethyl methacrylate (PMMA), polystyrene (PS), a polymer derivative having a phenol-based group, an acrylic polymer, an imide-based polymer, an aryl ether-based polymer, an amide-based polymer, a fluorinated polymer, a p-xylene-based polymer, a vinyl alcohol-based polymer, or a blend thereof.

A pixel electrode layer including a first, second, and third pixel electrodes PE1, PE2, and PE3 and auxiliary electrodes AE may be arranged over the insulating layer IL. The first pixel electrode PE1 may be a pixel electrode of the first light-emitting diode LED1 and may be electrically connected to the first pixel circuit PC1 through a contact portion penetrating the insulating layer IL. The second pixel electrode PE2 may be a pixel electrode of the second light-emitting diode LED2 and may be electrically connected to the second pixel circuit PC2 through a contact portion CNT2 penetrating the insulating layer IL. The third pixel electrode PE3 may be a pixel electrode of the third light-emitting diode LED3 and may be electrically connected to the third pixel circuit PC3 through a contact portion penetrating the insulating layer IL.

Each of the first to third pixel electrodes PE1, PE2, and PE3 and the auxiliary electrodes AE may include a (semi-) transparent electrode or a reflective electrode. For example, each of the first to third pixel electrodes PE1, PE2, and PE3 may include a reflective layer including at least one of silver (Ag), magnesium (Mg), Al, platinum (Pt), palladium (Pd), gold (Au), nickel (Ni), neodymium (Nd), iridium (Ir), chromium (Cr), and an alloy thereof, and a transparent or semi-transparent electrode layer arranged over the reflective layer. The transparent or semi-transparent electrode layer may include at least one of indium tin oxide (ITO), indium zinc oxide (IZO), ZnOₓ, In₂O₃, indium gallium oxide (IGO), and aluminum zinc oxide (AZO). For example, each of the first to third pixel electrodes PE1, PE2, and PE3 may have a three-layer structure of ITO/Ag/ITO.

The first pixel electrode PE1 may be spaced apart from the second pixel electrode PE2 and the third pixel electrode PE3 in the second direction (e.g., the y-direction). The second pixel electrode PE2 and the third pixel electrode PE3 may be adjacent to each other in a first direction (e.g., an x-direction) and may be spaced apart from each other. In a plan view, at least a portion of the first pixel electrode PE1 may overlap the first pixel circuit PC1, at least a portion of the second pixel electrode PE2 may overlap the second pixel circuit PC2, and at least a portion of the third pixel electrode PE3 may overlap the third pixel circuit PC3.

The second pixel electrode PE2 may include a protrusion PEp protruding in the second direction (e.g., the y-direction). In an embodiment, the protrusion PEp may be arranged adjacent to a portion that connects the gate electrode of the first transistor T1 and the second transistor T2 of the second pixel circuit PC2 to each other, for example, a portion constituting the first node N1 (see FIG. 4). When a repair process is performed on a defective pixel, the protrusion PEp may increase the capacitance of the storage capacitor Cst (see FIG. 4) of the second pixel circuit PC2, thereby improving the boost efficiency of the second pixel circuit PC2.

A bank layer BNL may be arranged over the insulating layer IL and the pixel electrode layer. The bank layer BNL may include at least one organic insulating material such as polyimide, polyamide, an acrylic resin, benzocyclobutene, and a phenol resin, and may be manufactured by a spin coating method, etc.

The bank layer BNL may have (or define) a first opening OP1 that exposes a central portion of the first pixel electrode PE1, a second opening OP2 that exposes a central portion of the second pixel electrode PE2, and a third opening OP3 that exposes a central portion of the third pixel electrode PE3, and may cover the edge of each of the first to third pixel electrodes PE1, PE2, and PE3. The bank layer BNL may prevent arcs or the like from occurring at the edges of each of the first to third pixel electrodes PE1, PE2, and PE3 by increasing the distance between the edge of each of the first to third pixel electrodes PE1, PE2, and PE3 and a common electrode 230.

An intermediate layer may be disposed between the first to third pixel electrodes PE1, PE2, and PE3 and the common electrode 230, and at least a portion of the intermediate layer may be arranged in an opening formed by the bank layer BNL. For example, the intermediate layer may include a first emission layer 223g arranged in the first opening OP1, a second emission layer 223b arranged in the second opening OP2, and a third emission layer (not shown) arranged in the third opening OP3. The emission layers may include an organic material including a fluorescent material or a phosphorescent material emitting red light, green light, or white light. Each emission layer may include a low-molecular weight organic material or a polymer organic material. In another embodiment, the emission layer may be commonly formed over multiple pixel electrodes.

The intermediate layer may include a first functional layer 221 and a second functional layer 225 commonly formed over multiple pixel electrodes. The first functional layer 221 may be disposed between the pixel electrodes and the emission layers, and the second functional layer 225 may be disposed between the emission layers and the common electrode 230. In an embodiment, each of the first functional layer 221 and the second functional layer 225 may include at least one of a hole transport layer (HTL), a hole injection layer (HIL), an electron transport layer (ETL), and an electron injection layer (EIL). In an embodiment, one of the first functional layer 221 and the second functional layer 225 may be omitted.

The first opening OP1 may define a first emission area EA1, which is an area where the first light-emitting diode LED1 emits light. The first pixel electrode PE1 may include the first emission area EA1, and a first non-emission area NEA1 surrounding the first emission area EA1 on the outside of the first emission area EA1. Similarly, the second opening OP2 may define a second emission area EA2, which is an area where the second light-emitting diode LED2 emits light. The second pixel electrode PE2 may include the second emission area EA2, and a second non-emission area NEA2 surrounding the second emission area EA2 on the outside of the second emission area EA2. The bank layer BNL may cover the first non-emission area NEA1 of the first pixel electrode PE1 and the second non-emission area NEA2 of the second pixel electrode PE2.

In an embodiment, the size (or area) of the first opening OP1, the size of the second opening OP2, and the size of the third opening OP3 may be different from each other in a plan view. For example, the first opening OP1 may be larger than the second opening OP2 and the third opening OP3. The second opening OP2 may be smaller than the third opening OP3. However, the disclosure is not limited thereto. In another embodiment, the sizes of the first opening OP1, the second opening OP2, and the third opening OP3 may be the same. In another embodiment, the first opening OP1 may be larger than the second opening OP2 and the third opening OP3, but the sizes of the second opening OP2 and the third opening OP3 may be the same.

The common electrode 230 may be arranged over the intermediate layer. The common electrode 230 may include a transmissive electrode or a reflective electrode. For example, the common electrode 230 may include a transparent or semi-transparent electrode and may include a metal thin-film having a low work function and including at least one of lithium (Li), calcium (Ca), lithium fluoride (LiF), Al, Ag, Mg, and a compound thereof. In an embodiment, the common electrode 230 may further include a transparent conductive oxide (TCO) layer, including ITO, IZO, ZnO, or In₂O₃, on the metal thin-film. The common electrode 230 may be integrally formed as a single body over the entire surface of the display area DA (see FIG. 1) and may be arranged over the pixel electrodes.

The first light-emitting diode LED1 may include the first pixel electrode PE1, the first functional layer 221, the first emission layer 223g, the second functional layer 225, and the common electrode 230. The second light-emitting diode LED2 may include the second pixel electrode PE2, the first functional layer 221, the second emission layer 223b, the second functional layer 225, and the common electrode 230.

The bank layer BNL may have an auxiliary opening AOP that exposes at least a portion of each auxiliary electrode AE. The first functional layer 221 and the second functional layer 225 may not overlap the auxiliary opening AOP in a plan view. In an embodiment, the first functional layer 221 and the second functional layer 225 may have an opening that overlaps the auxiliary opening AOP in a plan view. The common electrode 230 may be in direct contact with the auxiliary electrode AE through the auxiliary opening AOP. The auxiliary electrode AE may be connected to a power connection line configured to transmit the common power voltage ELVSS (see FIG. 4), and the common electrode 230 may be configured to receive the common power voltage ELVSS through the auxiliary electrode AE. Due to this structure, a luminance deviation of the display panel 10 due to a voltage drop of the common power voltage ELVSS may be reduced.

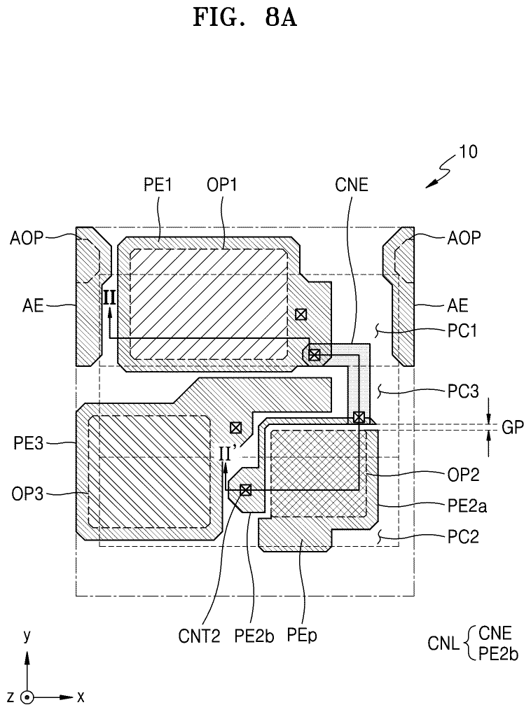

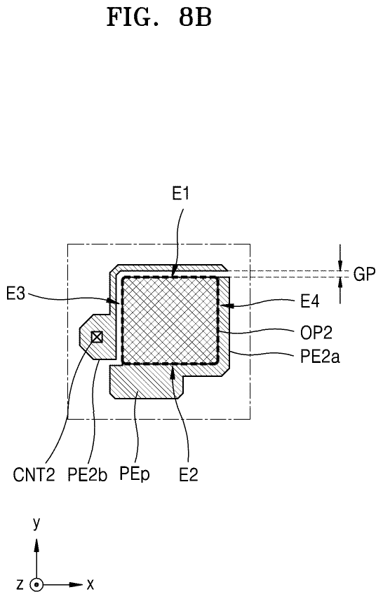

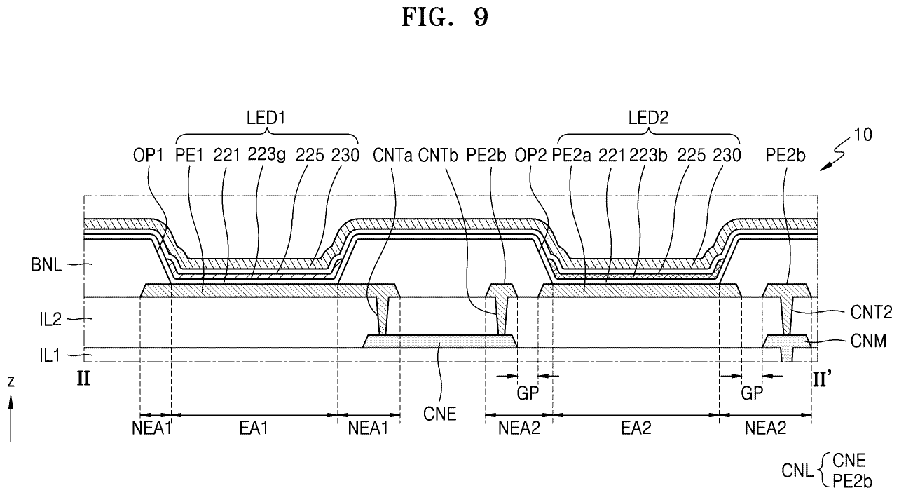

FIG. 8A is a schematic plan view of an area of the display panel 10 according to an embodiment, and FIG. 8B is a plan view illustrating a second pixel electrode shown in FIG. 8A. FIG. 9 is a schematic cross-sectional view of the display panel 10 taken along line II-II′ of FIG. 8A.

FIGS. 8A, 8B, and 9 schematically illustrate an area of the pixel PX (see FIG. 5) that has been repaired due to a defect in the first pixel circuit PC1.

Referring to FIGS. 8A, 8B, and 9, the display panel 10 may include a first insulating layer IL1 arranged over the substrate 100 (see FIG. 2). In an embodiment, the first insulating layer IL1 may include an inorganic insulating material and/or an organic insulating material. For example, the first insulating layer IL1 may include silicon oxide, silicon nitride, or silicon oxynitride. For example, the first insulating layer IL1 may include a photoresist, BCB, polyimide, HMDSO, PMMA, PS, a polymer derivative having a phenol-based group, an acrylic polymer, an imide-based polymer, an aryl ether-based polymer, an amide-based polymer, a fluorinated polymer, a p-xylene-based polymer, a vinyl alcohol-based polymer, or a blend thereof.

A connection electrode CNE and a contact metal CNM may be arranged on the first insulating layer IL1. Each of the connection electrode CNE and the contact metal CNM may include a conductive material such as molybdenum (Mo), Al, copper (Cu), Ti, or the like and may have a single layer or multilayer including the above material.

The connection electrode CNE and the first to third pixel electrodes PE1, PE2, and PE3 may be arranged on different layers. For example, the connection electrode CNE may be arranged below the first to third pixel electrodes PE1, PE2, and PE3 with a second insulating layer IL2 interposed between the connection electrode CNE and the first to third pixel electrodes PE1, PE2, and PE3.

In a plan view, the connection electrode CNE may have an end overlapping the first pixel electrode PE1 and another end overlapping the second pixel electrode PE2. In a plan view, the connection electrode CNE may have an isolated shape. In an embodiment, the connection electrode CNE may have a curved shape and spaced apart from the second pixel electrode PE2.

The connection electrode CNE may be arranged to be connectable to the first pixel electrode PE1 and the second pixel electrode PE2 in a normal pixel. The term “connectable” may refer to a state in which a connection may be made by laser or the like during a repair process. For example, in case that a first member and a second member are arranged to be connectable to each other, this may mean that the first member and the second member are not actually connected, but are in a state where they may be connected to each other during a repair process. From a structural point of view, the first member and the second member that are “connectable” to each other may overlap each other with an insulating layer therebetween. In case that a laser beam is irradiated to the overlapping area during a repair process, the insulating layer may be destroyed, allowing the first member and the second member to be electrically connected to each other.

The contact metal CNM may be electrically connected to the second pixel circuit PC2 through a contact portion penetrating the first insulating layer IL1. In another embodiment, the contact metal CNM may be omitted, and the contact portion CNT2 of the second pixel electrode PE2 may be electrically connected to the second pixel circuit PC2 through the first insulating layer IL1 and the second insulating layer IL2.

The second insulating layer IL2 may be arranged on the connection electrode CNE and the contact metal CNM. The second insulating layer IL2 and the insulating layer IL of FIG. 7 may have a same configuration. For example, the second insulating layer IL2 may include a planarization layer for providing a flat base surface on a pixel electrode layer. The second insulating layer IL2 may include an organic insulating material.

A pixel electrode layer including the first to third pixel electrodes PE1, PE2, and PE3 and the auxiliary electrodes AE may be arranged over the second insulating layer IL2. The first pixel electrode PE1 may be a pixel electrode of the first light-emitting diode LED1 and may be electrically connected to the second node N2 (see FIG. 4) of the first pixel circuit PC1. The third pixel electrode PE3 may be a pixel electrode of the third light-emitting diode LED3 and may be electrically connected to the second node N2 of the third pixel circuit PC3.

The bank layer BNL may be arranged over the second insulating layer IL2 and the pixel electrode layer. The bank layer BNL may have the first opening OP1 that exposes a central portion of the first pixel electrode PE1, the second opening OP2 that exposes a central portion of the second pixel electrode PE2, and the third opening OP3 that exposes a central portion of the third pixel electrode PE3, and may cover the edge of each of the first to third pixel electrodes PE1, PE2, and PE3. In an embodiment, the size (or area) of the first opening OP1, the size of the second opening OP2, and the size of the third opening OP3 may be different from each other in a plan view. For example, the first opening OP1 may be larger than the second opening OP2 and the third opening OP3. The second opening OP2 may be smaller than the third opening OP3. The bank layer BNL may have the auxiliary opening AOP that exposes at least a portion of the auxiliary electrode AE.

The intermediate layer may include the first emission layer 223g arranged in the first opening OP1, the second emission layer 223b arranged in the second opening OP2, and the third emission layer arranged in the third opening OP3. The intermediate layer may include the first functional layer 221 and the second functional layer 225 commonly formed over multiple pixel electrodes. The common electrode 230 may be arranged over the intermediate layer. The common electrode 230 may be commonly arranged over multiple pixel electrodes.

The bank layer BNL may have the auxiliary opening AOP that exposes at least a portion of the auxiliary electrode AE. In an embodiment, the first functional layer 221 and the second functional layer 225 may have an opening that overlaps the auxiliary opening AOP in a plan view. The common electrode 230 may be in direct contact with the auxiliary electrode AE through the auxiliary opening AOP.

During a manufacturing process of the display panel 10, the pixel electrode layer may be formed, and before the bank layer BNL is formed, a pixel circuit may be inspected for defects by using an optical method. During an inspection process, in case that a defect is identified in the first pixel circuit PC1, a repair process may be performed for the corresponding pixel PX.

As described above with reference to FIG. 5, in order to form a connection line CNL that electrically separates the second light-emitting diode LED2 and the second node N2 of the second pixel circuit PC2 from each other and electrically connects the first light-emitting diode LED1 and second node N2 of the second pixel circuit PC2 to each other, a laser beam may be irradiated to separate the second pixel electrode PE2 into two portions.

Through a repair process, the second pixel electrode PE2 may be separated into a first portion PE2a overlapping the second opening OP2 in a plan view, and a second portion PE2b spaced apart from the first portion PE2a with a gap GP between the second portion PE2b and the first portion PE2a. In a plan view, the gap GP formed by a laser beam may extend along a portion of the edge of the second opening OP2.

For example, as shown in FIG. 8B, the second opening OP2 may have an approximately rectangular shape in a plan view. The second opening OP2 may include a first edge E1 and a second edge E2 extending in the first direction (e.g., the x-direction), and a third edge E3 and a fourth edge E4 that connect the first edge E1 and the second edge E2 to each other and extend in the second direction (e.g., the y-direction). The first edge E1 may be an edge closer to the first pixel electrode PE1 than the second edge E2. The third edge E3 may be an edge adjacent to the contact portion CNT2 connected to the second pixel circuit PC2. The gap GP may extend along the first edge E1 and the third edge E3 and separate the first portion PE2a and the second portion PE2b from each other. The gap GP may surround a portion of the second emission area EA2 or the second opening OP2.

The first portion PE2a may include the second emission area EA2 and a portion of the second non-emission area NEA2. The second portion PE2b may include a remaining portion of the second non-emission area NEA2. In a plan view, the first portion PE2a may have an isolated shape and may thus be a dummy pixel electrode that is electrically separated from the second pixel circuit PC2 and does not emit. For example, the second light-emitting diode LED2 may include a light-emitting diode that does not emit light. The first portion PE2a may include a protrusion PEp protruding from the second pixel electrode PE2 in the second direction (e.g., the y-direction). The second portion PE2b may include a contact portion CNT2 penetrating the second insulating layer IL2. In a plan view, the second portion PE2b may surround a portion of the first portion PE2a and may have a shape roughly similar to an upside-down alphabet “L”. The contact portion CNT2 may be electrically connected to the second node N2 of the second pixel circuit PC2 through the contact metal CNM.

A laser beam may be irradiated to both ends of the connection electrode CNE to electrically connect an end of the connection electrode CNE to the first non-emission area NEA1 of the first pixel electrode PE1 and to electrically connect another end of the connection electrode CNE to the second portion PE2b of the second pixel electrode PE2. Through laser beam irradiation, contact holes penetrating the second insulating layer IL2 may be formed, and a portion of an electrode exposed by the laser beam may be instantly melted and solidified again to form contact portions CNTa and CNTb.

For example, in a normal pixel, the connection electrode CNE may be electrically connected to the first pixel electrode PE1 and the second pixel electrode PE2 by the second insulating layer IL2. In a pixel repaired due to a defect in the first pixel circuit PC1, the connection electrode CNE may be electrically connected to the first pixel electrode PE1 and the second portion PE2b of the second pixel electrode PE2 through the contact portions CNTa and CNTb penetrating the second insulating layer IL2.

The connection electrode CNE and the second portion PE2b of the second pixel electrode PE2 may form the connection line CNL. As described above with reference to FIG. 5, the connection line CNL may electrically connect the first pixel electrode PE1 and the second node N2 of the second pixel circuit PC2 to each other. Accordingly, even in case that a defect occurs in the first pixel circuit PC1, by electrically connecting the second pixel circuit PC2 and the first light-emitting diode LED1 to each other, the first light-emitting diode LED1 of the display panel 10 or the electronic apparatus DV may emit light to display high-quality images.

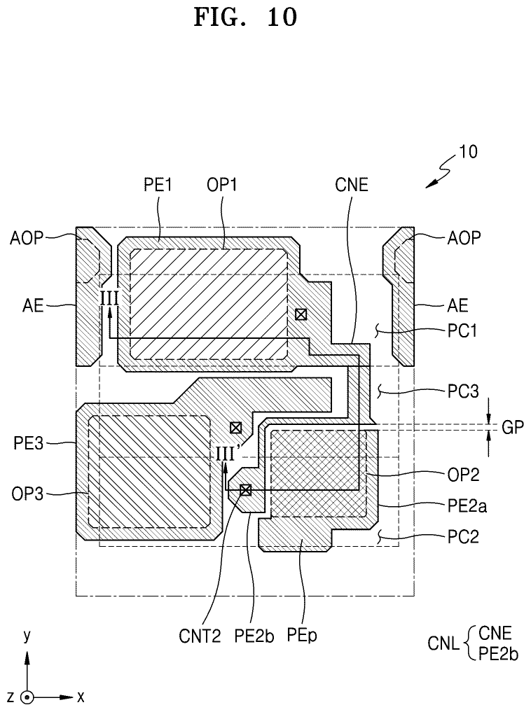

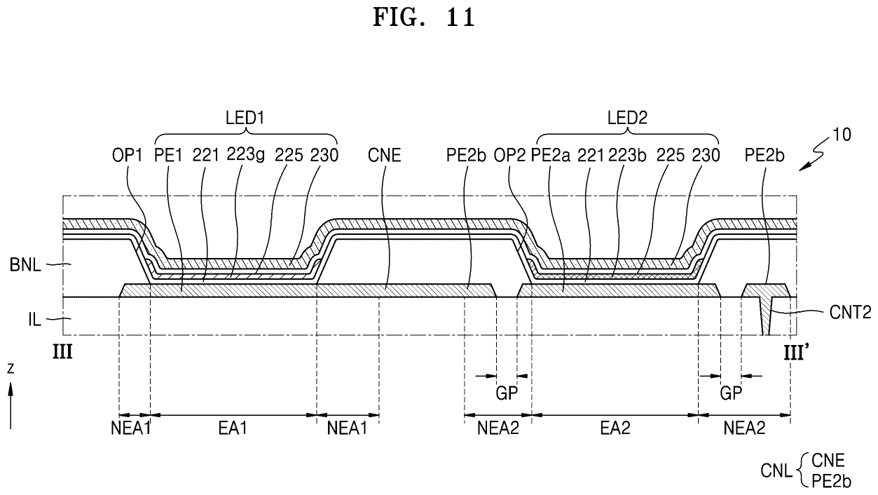

FIG. 10 is a schematic plan view of an area of the display panel 10 according to an embodiment, and FIG. 11 is a schematic cross-sectional view of the display panel 10 taken along line III-III′ of FIG. 10.

FIGS. 10 and 11 schematically illustrate an area of the pixel PX (see FIG. 5) that has been repaired due to a defect in the first pixel circuit PC1. Referring to FIGS. 10 and 11 together, the display panel 10 may include the insulating layer IL arranged over the substrate 100 (see FIG. 2).

A pixel electrode layer including the first to third pixel electrodes PE1, PE2, and PE3 and the auxiliary electrodes AE may be arranged over the insulating layer IL. The second pixel electrode PE2 may be separated into the first portion PE2a overlapping the second opening OP2 in a plan view, and the second portion PE2b spaced apart from the first portion PE2a with the gap GP between the second portion PE2b and the first portion PE2a. For example, the second emission layer 223b may be arranged above the first portion PE2a of the second pixel electrode PE2.

The first portion PE2a may include the second emission area EA2 and a portion of the second non-emission area NEA2. The second portion PE2b may include a remaining portion of the second non-emission area NEA2. The second opening OP2 may have an approximately rectangular shape in a plan view, and the gap GP may extend along a portion of the edge of the second opening OP2. In a plan view, the first portion PE2a may have an isolated shape and may thus be a dummy pixel electrode electrically separated from the second pixel circuit PC2. The first portion PE2a may include the protrusion PEp protruding from the second pixel electrode PE2 in the second direction (e.g., the y-direction). The second portion PE2b may include the contact portion CNT2 penetrating the second insulating layer IL2. The contact portion CNT2 may be electrically connected to the second node N2 of the second pixel circuit PC2.

The display panel 10 may include the connection electrode CNE that electrically connects the first pixel electrode PE1 and the second portion PE2b of the second pixel electrode PE2 to each other. The connection electrode CNE, the first to third pixel electrodes PE1, PE2, and PE3, and the auxiliary electrodes AE may be arranged on a same layer. For example, the connection electrode CNE may be disposed between the insulating layer IL and the bank layer BNL.

During a manufacturing process of the display panel 10, the pixel electrode layer may be formed, and before the bank layer BNL is formed, a pixel circuit may be inspected for defects by using an optical method. During an inspection process, in case that a defect is identified in the first pixel circuit PC1, a repair process may be performed for the corresponding pixel PX. Before the bank layer BNL is formed, the connection electrode CNE may be formed on the insulating layer IL. In an embodiment, the connection electrode CNE may be formed by dotting a conductive ink by using an inkjet printing method. The conductive ink may include a conductive material, and the conductive material may include copper nanoparticles, silver nanoparticles, or graphene particles.

For example, the connection electrode CNE may not be present in a normal pixel. In a pixel repaired due to a defect in the first pixel circuit PC1, an end of the connection electrode CNE may be connected to the first pixel electrode PE1, and another end of the connection electrode CNE may be connected to the second portion PE2b of the second pixel electrode PE2.

The connection electrode CNE and the second portion PE2b of the second pixel electrode PE2 may form the connection line CNL. The connection line CNL may electrically connect the first pixel electrode PE1 and the second node N2 of the second pixel circuit PC2 to each other. Accordingly, the display panel 10 wherein, even in case that a defect occurs in the first pixel circuit PC1, by electrically connecting the second pixel circuit PC2 and the first light-emitting diode LED1 to each other, the display panel 10 or the electronic apparatus DV may display high-quality images.

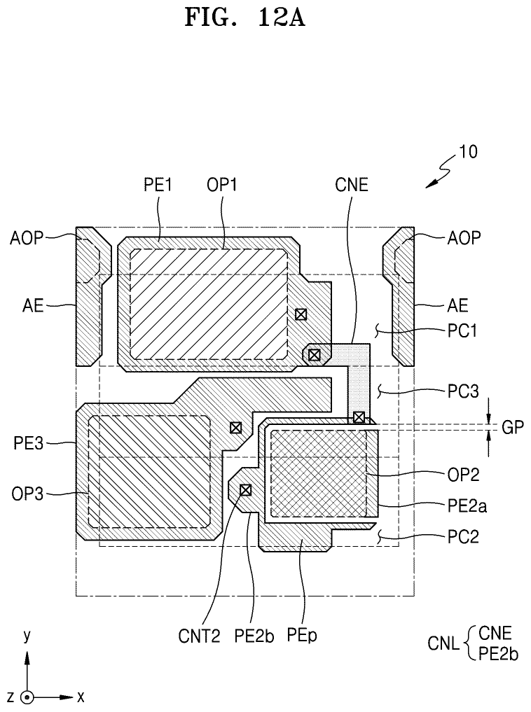

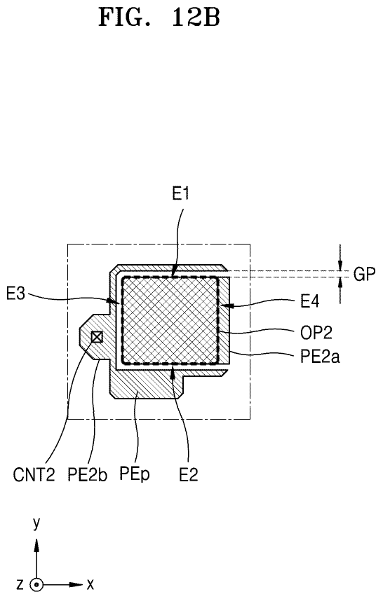

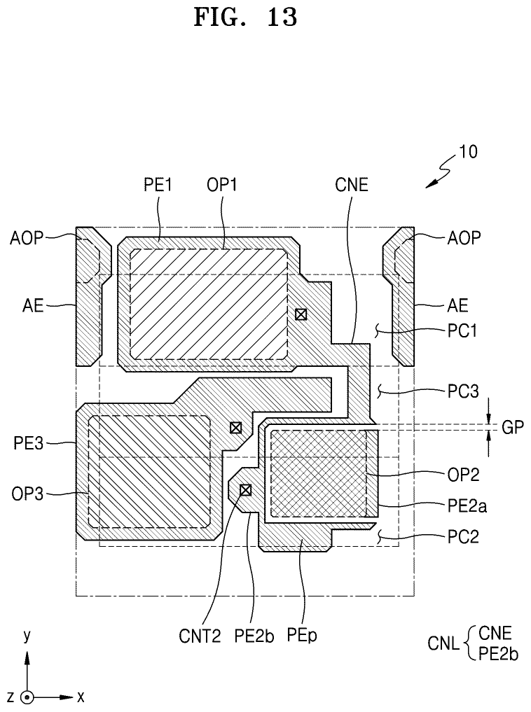

FIG. 12A is a schematic plan view of an area of the display panel 10 according to an embodiment, and FIG. 12B is a plan view illustrating a second pixel electrode shown in FIG. 12A. FIG. 13 is a schematic plan view of an area of the display panel 10 according to an embodiment.

FIGS. 12A, 12B, and 13 schematically illustrate an area of the pixel PX (see FIG. 5) that has been repaired due to a defect in the first pixel circuit PC1. FIG. 13 may be similar to FIG. 12A, but shows an embodiment that the connection electrode CNE, the first to third pixel electrodes PE1, PE2, and PE3, and the auxiliary electrodes AE are arranged on a same layer.

Referring to FIGS. 12A and 12B, the display panel 10 may include the first to third pixel electrodes PE1, PE2, and PE3 and the auxiliary electrodes AE.

The bank layer BNL (see FIG. 7) may be arranged over the first to third pixel electrodes PE1, PE2, and PE3 and the auxiliary electrodes AE. The bank layer BNL may have the first opening OP1 that exposes a central portion of the first pixel electrode PE1, the second opening OP2 that exposes a central portion of the second pixel electrode PE2, and the third opening OP3 that exposes a central portion of the third pixel electrode PE3, and may cover the edge of each of the first to third pixel electrodes PE1, PE2, and PE3.

In an embodiment, the size (or area) of the first opening OP1, the size of the second opening OP2, and the size of the third opening OP3 may be different from each other in a plan view. For example, the first opening OP1 may be larger than the second opening OP2 and the third opening OP3. The second opening OP2 may be smaller than the third opening OP3. The bank layer BNL may have the auxiliary opening AOP that exposes at least a portion of each auxiliary electrode AE. The common electrode 230 (see FIG. 7) may be in contact with the auxiliary electrode AE through the auxiliary opening AOP.

The connection electrode CNE and the first to third pixel electrodes PE1, PE2, and PE3 may be arranged on different layers. For example, the connection electrode CNE may be arranged below the first to third pixel electrodes PE1, PE2, and PE3 with at least one insulating layer interposed between the connection electrode CNE and the first to third pixel electrodes PE1, PE2, and PE3. In a plan view, the connection electrode CNE may have an end overlapping the first pixel electrode PE1 and another end overlapping the second pixel electrode PE2. In a plan view, the connection electrode CNE may have an isolated shape. In an embodiment, in a plan view, the connection electrode CNE may have a curved shape to be spaced apart from the second pixel electrode PE2.

Through a repair process, the second pixel electrode PE2 (see FIG. 6) may be separated into the first portion PE2a overlapping the second opening OP2 in a plan view, and the second portion PE2b spaced apart from the first portion PE2a with the gap GP between the second portion PE2b and the first portion PE2a. In a plan view, the gap GP formed by a laser beam may extend along a portion of the edge of the second opening OP2.

For example, as shown in FIG. 12B, the second opening OP2 may have an approximately rectangular shape in a plan view. The second opening OP2 may include the first edge E1 and the second edge E2 extending in the first direction (e.g., the x-direction), and the third edge E3 and the fourth edge E4 that connect the first edge E1 and the second edge E2 to each other and extend in the second direction (e.g., the y-direction). The first edge E1 may be an edge closer to the first pixel electrode PE1 than the second edge E2. The third edge E3 may be an edge adjacent to the contact portion CNT2 connected to the second pixel circuit PC2. The gap GP may extend along the first edge E1, the third edge E3, and the second edge E2 and separate the first portion PE2a and the second portion PE2b from each other.

The first portion PE2a may include the second emission area EA2 and a portion of the second non-emission area NEA2 adjacent to the fourth edge E4. The second portion PE2b may include a remaining portion of the second non-emission area NEA2. In a plan view, the first portion PE2a may have an isolated shape and may thus be a dummy pixel electrode electrically separated from the second pixel circuit PC2. For example, the second light-emitting diode LED2 may include a light-emitting diode that does not emit light. In a plan view, the second portion PE2b may surround a portion of the first portion PE2a and may have a shape roughly similar to an alphabet “C”. The second portion PE2b may include the protrusion PEp protruding in the second direction (e.g., the y-direction).

In a normal pixel, the connection electrode CNE may be electrically insulated from the first pixel electrode PE1 and the second pixel electrode PE2 by an insulating layer. In other words, in a normal pixel, the connection electrode CNE may be arranged to be connectable to the first pixel electrode PE1 and the second pixel electrode PE2. In a pixel repaired due to a defect in the first pixel circuit PC1, the connection electrode CNE may be electrically connected to the first pixel electrode PE1 and the second portion PE2b of the second pixel electrode PE2 through contact portions penetrating the insulating layer.

The connection electrode CNE and the second portion PE2b of the second pixel electrode PE2 may form the connection line CNL. As described above with reference to FIG. 5, the connection line CNL may electrically connect the first pixel electrode PE1 and the second node N2 of the second pixel circuit PC2 to each other.

Referring to FIG. 13, the display panel 10 may include the connection electrode CNE that electrically connects the first pixel electrode PE1 and the second portion PE2b of the second pixel electrode PE2 to each other. The connection electrode CNE, the first to third pixel electrodes PE1, PE2, and PE3, and the auxiliary electrodes AE may be arranged on a same layer. For example, as described above with reference to FIG. 11, the connection electrode CNE may be disposed between the insulating layer IL and the bank layer BNL.

Through a repair process, the second pixel electrode PE2 (see FIG. 6) may be separated into the first portion PE2a overlapping the second opening OP2 in a plan view, and the second portion PE2b spaced apart from the first portion PE2a with the gap GP between the second portion PE2b and the first portion PE2a. In a plan view, the second portion PE2b may surround a portion of the first portion PE2a and may have a shape roughly similar to an alphabet “C”. The second portion PE2b may include the protrusion PEp protruding in the second direction (e.g., the y-direction).

Before the bank layer BNL is formed, the connection electrode CNE may be formed on the insulating layer IL (see FIG. 7). For example, the connection electrode CNE may not be present in the normal pixel. In a pixel repaired due to a defect in the first pixel circuit PC1, an end of the connection electrode CNE may be connected to the first pixel electrode PE1, and another end of the connection electrode CNE may be connected to the second portion PE2b of the second pixel electrode PE2.

The connection electrode CNE and the second portion PE2b of the second pixel electrode PE2 may form the connection line CNL. The connection line CNL may electrically connect the first pixel electrode PE1 and the second node N2 of the second pixel circuit PC2 to each other.

The boost efficiency of a single subpixel may be determined based on a ratio between capacitance of the storage capacitor Cst (see FIG. 4) and parasitic capacitance between other elements. In a repaired pixel PX, the second pixel circuit PC2 may be connected to the first data line DL1 (see FIG. 4) and configured to receive the first data signal DATA1 (see FIG. 4). Parasitic capacitance may increase due to the connection line CNL that connects the second pixel circuit PC2 and the first light-emitting diode LED1 to each other. Accordingly, a luminance deviation may occur between the first light-emitting diode LED1 of the normal pixel and the first light-emitting diode LED1 of the repaired pixel due to the difference in boost efficiency between the first pixel circuit PC1 and the second pixel circuit PC2.

In the embodiment, the second portion PE2b of the second pixel electrode PE2 may include the protrusion PEp, thereby reducing the difference in boost efficiency between the normal pixel and the repaired pixel. For example, the protrusion PEp may be arranged adjacent to a portion that connects the gate electrode of the first transistor T1 and the second transistor T2 of the second pixel circuit PC2 to each other, for example, a portion constituting the first node N1 (see FIG. 4), thereby increasing the capacitance of the storage capacitor Cst of the second pixel circuit PC2.

TABLE 1

| Category | Normal pixel | Embodiment 1 | Embodiment 2 |
|---|---|---|---|
| Boost | 97.7% | 96.1% | 97.3% |
| efficiency | | | |
| Current | — | −14.4% | −4.8% |
| change | | | |
| amount | | | |

As shown in FIG. 8B, Embodiment 1 is a repaired pixel in which the second pixel electrode PE2 is separated so that the protrusion PEp is included in the first portion PE2a of the second pixel electrode PE2, and as shown in FIG. 12B, Embodiment 2 is a repaired pixel in which the second pixel electrode PE2 is separated so that the protrusion PEp is included in the second portion PE2b of the second pixel electrode PE2.

The boost efficiency of Embodiment 1 is decreased by 1.6% compared to the boost efficiency of a normal pixel, while the boost efficiency of Embodiment 2 is decreased by only 0.3% compared to the boost efficiency of the normal pixel. Also, in Embodiment 1, it was identified that a driving current for driving the first light-emitting diode LED1 was reduced by 14.4% compared to the normal pixel, but in Embodiment 2, it was identified that a driving current for driving the first light-emitting diode LED1 was reduced by 4.8% compared to the normal pixel.

Accordingly, in the display panel 10 according to embodiments, the second portion PE2b of the second pixel electrode PE2 constituting the connection line CNL may include the protrusion PEp, thereby providing high-quality images with improved luminance difference between the normal pixel and the repaired pixel.

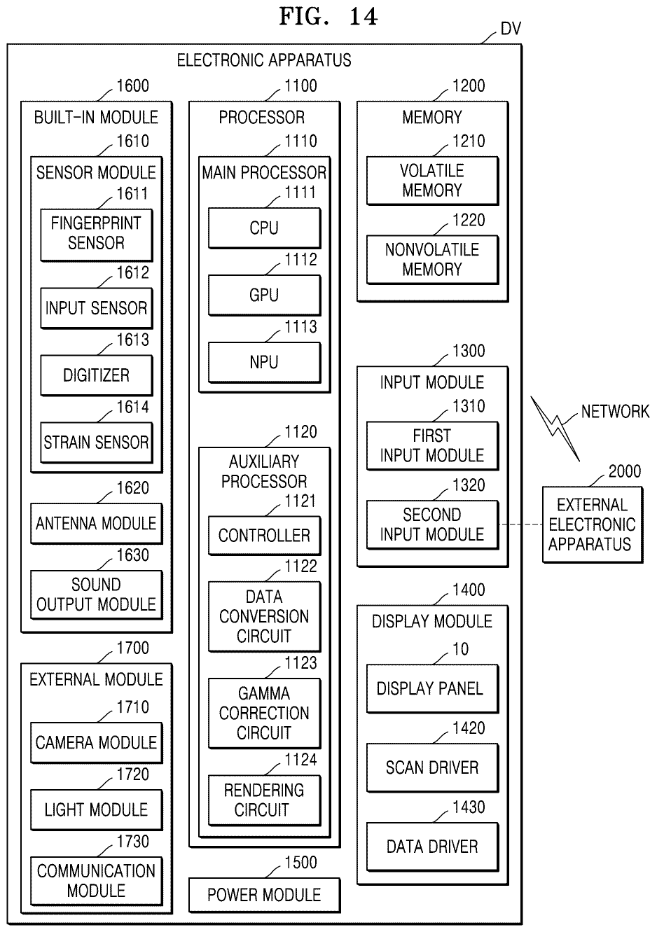

FIG. 14 is a schematic block diagram of the electronic apparatus DV according to an embodiment.

Referring to FIG. 14, the electronic apparatus DV may include a processor 1100, a memory 1200, an input module 1300, a display module 1400, a power module 1500, a built-in module 1600, and an external module 1700. According to an embodiment, in the electronic apparatus DV, at least one of the components may be omitted, or one or more other components may be added. According to an embodiment, some (e.g., the built-in module 1600) of the components may be integrated into another component (e.g., the display module 1400).

The processor 1100 may execute software to control at least one other component (e.g., a hardware or software component) of the electronic apparatus DV connected to the processor 1100, and may perform various data processing or operations. According to an embodiment, as at least a portion of data processing or operation, the processor 1100 may store, in a volatile memory 1210, commands or data received from another component (e.g., the input module 1300, a sensor module 1610, or a communication module 1730), process the commands or data stored in the volatile memory 1210, and store result data in a nonvolatile memory 1220.

The processor 1100 may include a main processor 1110 and an auxiliary processor 1120. The main processor 1110 may include at least one of a central processing unit (CPU) 1111 and an application processor (AP). The main processor 1110 may further include at least one of a graphic processing unit (GPU) 1112, a communication processor (CP), and an image signal processor (ISP). The main processor 1110 may further include a neural processing unit (NPU) 1113. The NPU 1113 may be a processor specialized in processing an artificial intelligence model, and the artificial intelligence model may be generated through machine learning. The artificial intelligence model may include multiple artificial neural network layers. An artificial neural network may include one of a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination of two or more of the aforementioned networks, but the disclosure is not limited to the examples described above. The artificial intelligence model may additionally or alternatively include a software structure in addition to a hardware structure. At least two of the processing units or processors described above may be implemented as a single integrated component (e.g., a single chip) or may each be implemented as an independent component (e.g., multiple chips).

The auxiliary processor 1120 may include a controller 1121. The controller 1121 may include an interface conversion circuit and a timing control circuit. The controller 1121 may receive an image signal from the main processor 1110, convert the data format of the image signal to match interface specifications of the display module 1400, and output image data. The controller 1121 may output various control signals for driving the display module 1400.

The auxiliary processor 1120 may further include data processing circuits, such as a data conversion circuit 1122, a gamma correction circuit 1123, or a rendering circuit 1124. The data conversion circuit 1122 may receive the image data from the controller 1121 and may compensate the image data so that an image is displayed at a desired brightness according to characteristics of the electronic apparatus DV or user settings, or may convert the image data to reduce power consumption or compensate for an afterimage. The gamma correction circuit 1123 may convert the image data or a gamma reference voltage so that an image displayed on the electronic apparatus DV has desired gamma characteristics. The rendering circuit 1124 may receive image data from the controller 1121 and render the image data by taking into consideration a pixel layout of the display panel 10 applied to the electronic apparatus DV.

The memory 1200 may store various types of data used by at least one component (e.g., the processor 1100 or the sensor module 1610) of the electronic apparatus DV, and input data or output data for commands related thereto. The memory 1200 may include at least one of the volatile memory 1210 and the nonvolatile memory 1220.

The input module 1300 may receive commands or data to be used for a component (e.g., the processor 1100, the sensor module 1610, or a sound output module 1630) of the electronic apparatus DV from an external source (e.g., a user or an external electronic apparatus 2000) of the electronic apparatus DV.

The input module 1300 may include a first input module 1310 into which commands or data are input from the user, and a second input module 1320 into which commands or data are input from the external electronic apparatus 2000.

The first input module 1310 may include a microphone, a mouse, a keyboard, or a pen (e.g., a passive pen or an active pen). The first input module 1310 may include a mechanical input means or a touch input means, such as a button, a dome switch, a jog wheel, or a jog switch, arranged on the rear surface or side surface of the electronic apparatus DV.

The second input module 1320 may be connected via wires or wirelessly to various types of external electronic apparatuses 2000 connected to the electronic apparatus DV. According to an embodiment, the second input module 1320 may include a high definition multimedia interface (HDMI), a universal serial bus (USB) interface, a secure digital (SD) card interface, or an audio interface. The second input module 1320 may include a connector capable of physically connecting the electronic apparatus DV to the external electronic apparatus 2000, for example, an HDMI connector, a USB connector, an SD card connector, or an audio connector (e.g., a headphone connector). In response to the external electronic apparatus 2000 being connected to the second input module 1320, the electronic apparatus DV may perform appropriate control related to the connected external electronic apparatus 2000.

The display module 1400 may visually provide information to a user. The display module 1400 may include the display panel 10, a scan driver 1420, and the data driver 1430. The display module 1400 may further include a window, a chassis, a bracket, a supporter, or a heat dissipation member to protect or support the display panel 10.

The display panel 10 may display (output) information processed by the electronic apparatus DV. The display panel 10 may display execution screen information about an application running on the electronic apparatus DV, or user interface (UI) or graphic user interface (GUI) information according to the execution screen information. The display panel 10 may include a liquid crystal display panel, an organic light-emitting display panel, or an inorganic light-emitting display panel, and the type of the display panel 10 is not particularly limited. The display panel 10 may be a rigid display panel or a flexible display panel that is rollable or foldable.

The scan driver 1420 may be mounted on the display panel 10 as a driving chip. In another embodiment, the scan driver 1420 may be formed directly on the display panel 10. For example, the scan driver 1420 may include an amorphous silicon thin-film transistor (TFT) gate driver circuit (AGS), a low-temperature polycrystalline silicon (LTPS) TFT gate driver circuit, or an oxide semiconductor TFT gate driver circuit (OSG) embedded in the display panel 10. The scan driver 1420 may receive a control signal from the controller 1121 and output scan signals to the display panel 10 in response to the control signal. The display panel 10 may further include an emission control driver. The emission control driver may output an emission control signal to the display panel 10 in response to the control signal received from the controller 1121. The emission control driver may be formed separately from the scan driver 1420 or may be integrated into the scan driver 1420.

The data driver 1430 may receive a control signal from the controller 1121, convert image data into data voltages in the form of analog voltages in response to the control signal, and output the data voltages to the display panel 10.

The power module 1500 may supply power to the components of the electronic apparatus DV. The power module 1500 may include a battery configured to charge a power voltage. For example, the power module 1500 may include a connection port, and the connection port may be included in the second input module 1320 to which an external charger is connected, the external charger being configured to supply power for charging the battery. For example, the power module 1500 may include a wireless power transmission/reception member to enable wireless charging of the battery. The wireless power transmission/reception member may include multiple coil-shaped antenna radiators. The power module 1500 may include a power management IC (PMIC). The PMIC may supply optimized power to each component of the electronic apparatus DV.

The electronic apparatus DV may further include the built-in module 1600 and the external module 1700. The built-in module 1600 may include the sensor module 1610, an antenna module 1620, and the sound output module 1630. The external module 1700 may include a camera module 1710, a light module 1720, and the communication module 1730.

The sensor module 1610 may detect an input made by a body of a user or an input made by a pen, and generate an electrical signal or a data value corresponding to the input. The sensor module 1610 may include at least one of a fingerprint sensor 1611, an input sensor 1612, a digitizer 1613, and a strain sensor 1614.

The fingerprint sensor 1611 may generate a data value corresponding to a fingerprint of the user. The fingerprint sensor 1611 may include either an optical fingerprint sensor or a capacitive fingerprint sensor.

The input sensor 1612 may generate a data value corresponding to coordinate information about the input made by the body of the user or the input made by the pen. The input sensor 1612 may generate a data value based on a change in electrostatic capacitance due to the input. The input sensor 1612 may detect an input made by the passive pen or transmit and receive data to and from the active pen.

The input sensor 1612 may measure a biosignal, such as blood pressure, moisture, or body fat. For example, in case that a user touches a part of his or her body on a sensor layer or a sensing panel and does not move for a certain period of time, the input sensor 1612 may detect a biosignal based on a change in an electric field caused by the part of the body and output, to the display module 1400, information desired by the user.

The digitizer 1613 may generate a data value corresponding to the coordinate information about the input made by the pen. The digitizer 1613 may generate a data value based on a change in an electromagnetic force caused by the input. The digitizer 1613 may detect an input made by the passive pen or transmit and receive data to and from the active pen.

In an embodiment, at least one of the fingerprint sensor 1611, the input sensor 1612, the digitizer 1613, and the strain sensor 1614 may be embedded in the display panel 10. For example, at least one of the fingerprint sensor 1611, the input sensor 1612, the digitizer 1613, and the strain sensor 1614 may be formed through a process that is continuous with a process of forming pixel circuits and light-emitting diodes of the display panel 10. Due to this, the display panel 10 may function as one of inputters configured to provide an input interface between the electronic apparatus DV and a user and may also function as one of outputters configured to provide an output interface between the electronic apparatus DV and the user.

In another embodiment, at least two of the fingerprint sensor 1611, the input sensor 1612, the digitizer 1613, and the strain sensor 1614 may be formed to be integrated into one sensing panel through a same process. The sensing panel may be disposed between the display panel 10 and a window arranged on top of the display panel 10, but the disclosure is not limited thereto.

The antenna module 1620 may include one or more antennas for transmitting or receiving signals or power to or from the outside. According to an embodiment, the communication module 1730 may transmit or receive a signal to or from an external electronic apparatus 2000 through an antenna suitable for a communication method. An antenna pattern of the antenna module 1620 may be integrated into one component (e.g., the display panel 10) of the display module 1400 or the input sensor 1612.

The sound output module 1630 may be an apparatus for outputting a sound signal to the outside of the electronic apparatus DV and may output sound data received from the communication module 1730 or stored in the memory 1200 in a call signal reception mode, a call mode, a recording mode, a speech recognition mode, or a broadcasting mode. The sound output module 1630 may output a sound signal related to a function (e.g., a call signal reception sound, a message reception sound, or the like) performed by the electronic apparatus DV. The sound output module 1630 may include a receiver and a speaker. At least one of the receiver and the speaker may include a sound generation apparatus that is attached to the bottom of the display panel 10 and vibrates the display panel 10 to output sound. The sound generation apparatus may include a piezoelectric element or a piezoelectric actuator that contracts and expands in response to an electrical signal, or an exciter that vibrates the display panel 10 by generating a magnetic force by using a voice coil.

The camera module 1710 may capture still images or record videos. According to an embodiment, the camera module 1710 may include one or more lenses, image sensors, or ISPs. The camera module 1710 may further include an infrared camera capable of measuring the presence of a user, a location of the user, and a gaze of the user.

The light module 1720 may output a signal for notifying of the occurrence of an event by using a light source or provide light for obtaining images. Examples of the occurrence of the event may include receiving a message, receiving a call signal, a missed call, an alarm, a schedule reminder, receiving an email, or notifying of battery charge capacity information. The light module 1720 may include a light-emitting diode or a xenon lamp. The light module 1720 may emit light of a single color or multiple colors to the front surface or rear surface of the electronic apparatus DV. The light module 1720 may operate in conjunction with the camera module 1710 or operate independently.

The communication module 1730 may support the establishment of a wired or wireless communication channel between the electronic apparatus DV and the external electronic apparatus 2000 and the performance of communication via the established communication channel. The communication module 1730 may include one or both of a wireless communication module, such as a cellular communication module, a short-range communication module, or a global navigation satellite system (GNSS) communication module, and a wired communication module, such as a local area network (LAN) communication module or a power line communication module. The communication module 1730 may transmit and receive wireless signals over the Internet by using at least one of wireless LAN (WLAN), wireless-fidelity (Wi-Fi), Wi-Fi direct, and digital living network alliance (DLNA) technologies. Also, the communication module 1730 may support short-range communication by using at least one of Bluetooth™, radio frequency identification (RFID), infrared data association (IrDA), ultra-wideband (UWB), ZigBee, near-field communication (NFC), Wi-Fi, Wi-Fi direct, and wireless USB technologies. The various types of communication modules 1730 described above may be implemented as a single chip or as separate chips.

The electronic apparatus DV may output various types of information through the display module 1400 in an operating system. In case that the processor 1100 executes an application stored in the memory 1200, the display module 1400 may provide application information to a user through the display panel 10.

Based on input data received from the input module 1300 or the sensor module 1610, the processor 1100 may output commands or data to the display module 1400, the sound output module 1630, the camera module 1710, or the light module 1720. For example, the processor 1100 may generate image data corresponding to the input data and output the image data to the display module 1400, or may generate command data corresponding to the input data and output the command data to the camera module 1710 or the light module 1720. In case that the input data is not received from the input module 1300 for a certain period of time, the processor 1100 may reduce power consumption of the electronic apparatus DV by switching an operation mode of the electronic apparatus DV to a lower power mode or a sleep mode.

The processor 1100 may obtain an external input through the input module 1300 or the sensor module 1610 and execute an application corresponding to the external input. For example, in case that a user selects a camera icon displayed on the display panel 10, the processor 1100 may obtain a user input through the input sensor 1612 and activate the camera module 1710. The processor 1100 may transmit, to the display module 1400, image data corresponding to a captured image obtained by the camera module 1710. The display module 1400 may display, through the display panel 10, an image corresponding to the captured image.

For example, in case that personal information authentication is performed in the display module 1400, the fingerprint sensor 1611 may obtain input fingerprint information as input data. The processor 1100 may compare the input data obtained through the fingerprint sensor 1611 with authentication data stored in the memory 1200 and execute an application based on a result of the comparison. The display module 1400 may display, through the display panel 10, information executed according to the logic of the application.

For example, in case that a music streaming icon displayed on the display module 1400 is selected, the processor 1100 may obtain a user input through the input sensor 1612 and activate a music streaming application stored in the memory 1200. In case that a music execution command is input in the music streaming application, the processor 1100 may activate the sound output module 1630 and provide, to a user, sound information corresponding to the music execution command.

Some of the elements may be connected to each other by using a communication method, for example, a bus, a general purpose input/output (GPIO), a serial peripheral interface (SPI), a mobile industry processor interface (MIPI), or an ultra-path interconnect (UPI) link, between peripheral devices, and exchange signals (e.g., commands or data) with each other. In an embodiment, the main processor 1110 may transmit an image signal to the auxiliary processor 1120 via the MIPI.

According to the one or more embodiments as described above, a display panel that displays high-quality images and an electronic apparatus including the same may be implemented. However, the scope of the disclosure is not limited by the above effects.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display panel comprising:
a pixel circuit set including a first pixel circuit, a second pixel circuit, and a third pixel circuit;
a first pixel electrode overlapping the first pixel circuit in a plan view;
a second pixel electrode overlapping the second pixel circuit in a plan view;
a third pixel electrode overlapping the third pixel circuit in a plan view; and
a connection electrode arranged below the first pixel electrode, the second pixel electrode, and the third pixel electrode,
wherein, in a plan view, an end of the connection electrode overlaps the first pixel electrode, and another end of the connection electrode overlaps the second pixel electrode.

2. The display panel of claim 1, further comprising:
a bank layer arranged over the first pixel electrode, the second pixel electrode, and the third pixel electrode, the bank layer including a first opening overlapping the first pixel electrode, a second opening overlapping the second pixel electrode, and a third opening overlapping the third pixel electrode in a plan view.

3. The display panel of claim 2, wherein
the first opening is larger than the second opening and the third opening in a plan view, and
the second opening is smaller than the third opening in a plan view.

4. The display panel of claim 2, wherein
the second pixel electrode includes a first portion and a second portion, the first portion overlapping the second opening in a plan view, and the second portion being spaced apart from the first portion with a gap between the first portion and the second portion, and
in a plan view, the gap extends along a portion of an edge of the second opening.

5. The display panel of claim 4, wherein
the second portion includes a contact portion electrically connected to the second pixel circuit, and
the connection electrode connects the first pixel electrode and the second portion to each other.

6. The display panel of claim 4, wherein
the second pixel electrode and the third pixel electrode are adjacent to each other in a first direction, and
the second pixel electrode includes a protrusion protruding in a second direction intersecting the first direction.

7. The display panel of claim 6, wherein the second portion includes the protrusion.

8. The display panel of claim 1, wherein each of the first pixel circuit, the second pixel circuit, and the third pixel circuit comprises:
a first transistor including a gate, a first terminal, and a second terminal, the gate being connected to a first node, the first terminal being connected to a driving voltage line, and the second terminal being connected to a second node;
a second transistor connected between the first node and one of a first data line, a second data line, and a third data line;
a third transistor connected between an initialization-sensing line and the second node; and
a capacitor connected between the first node and the second node.

9. The display panel of claim 8, wherein
the second transistor of the first pixel circuit is connected to the first data line,
the second node of the first pixel circuit is connected to the first pixel electrode,
the second transistor of the second pixel circuit is connected to the second data line,
the second node of the second pixel circuit is connected to the second pixel electrode,
the third transistor of the third pixel circuit is connected to the third data line, and
the second node of the third pixel circuit is connected to the third pixel electrode.

10. The display panel of claim 8, wherein
the second transistor of the second pixel circuit is connected to the first data line, and
the second node of the second pixel circuit is connected to the first pixel electrode.

11. A display panel comprising:
a pixel circuit set including a first pixel circuit, a second pixel circuit, and a third pixel circuit;
a first pixel electrode overlapping the first pixel circuit in a plan view;
a second pixel electrode overlapping the second pixel circuit in a plan view;
a third pixel electrode overlapping the third pixel circuit in a plan view; and
a connection electrode that connects the first pixel electrode and the second pixel electrode to each other,
wherein the second pixel electrode includes a first portion and a second portion, the second portion being spaced apart from the first portion with a gap between the first portion and the second portion and connected to the connection electrode.

12. The display panel of claim 11, further comprising:
a bank layer arranged over the first pixel electrode, the second pixel electrode, and the third pixel electrode, the bank layer including a first opening overlapping the first pixel electrode, a second opening overlapping the second pixel electrode, and a third opening overlapping the third pixel electrode in a plan view.

13. The display panel of claim 12, wherein
the first opening is larger than the second opening and the third opening in a plan view, and
the second opening is smaller than the third opening in a plan view.

14. The display panel of claim 12, wherein, in a plan view, the gap extends along a portion of an edge of the second opening.

15. The display panel of claim 11, wherein
the second portion includes a contact portion electrically connected to the second pixel circuit, and
the connection electrode connects the first pixel electrode and the second portion to each other.

16. The display panel of claim 11, wherein
the second pixel electrode and the third pixel electrode are adjacent to each other in a first direction, and
the second pixel electrode includes a protrusion protruding in a second direction intersecting the first direction.

17. The display panel of claim 16, wherein the first portion includes the protrusion.

18. The display panel of claim 16, wherein the second portion includes the protrusion.

19. An electronic apparatus comprising:
a display panel; and
a processor that drives the display panel, wherein
the display panel comprises:
a pixel circuit set including a first pixel circuit, a second pixel circuit, and a third pixel circuit;
a first pixel electrode overlapping the first pixel circuit in a plan view;
a second pixel electrode overlapping the second pixel circuit in a plan view;
a third pixel electrode overlapping the third pixel circuit in a plan view; and
a connection electrode that connects the first pixel electrode and the second pixel electrode to each other, and
the second pixel electrode includes a first portion and a second portion, the second portion being spaced apart from the first portion with a gap between the first portion and the second portion and connected to the connection electrode.

20. The electronic apparatus of claim 19, wherein
the connection electrode is arranged below the first pixel electrode, the second pixel electrode, and the third pixel electrode, and
in a plan view, an end of the connection electrode overlaps the first portion of the first pixel electrode, and another end of the connection electrode overlaps the second pixel electrode.
